(19) United States
(12) Patent Application Publication
(10) Pub. No.: US 2025/0089536 A1
(43) Pub. Date: Mar. 13, 2025

(54) DISPLAY DEVICE AND METHOD FOR FABRICATING THE SAME

(71) Applicant: SAMSUNG DISPLAY CO., LTD., YONGIN-SI (KR)

(72) Inventors: Young Rok KIM, Yongin-si (KR); Woo Jin CHO, Yongin-si (KR)

(21) Appl. No.: 18/661,996

(22) Filed: May 13, 2024

(30) Foreign Application Priority Data
Sep. 11, 2023 (KR) 10-2023-0120378

(51) Int. Cl. H10K 59/80; H10K 59/12; H10K 59/122; H10K 59/131; H10K 59/38; H10K 71/60

(52) U.S. Cl. CPC H10K 59/878; H10K 59/1201; H10K 59/122; H10K 59/131; H10K 59/38; H10K 71/60

(57) ABSTRACT

Provided is a display device comprising an interlayer insulating layer on a substrate and having a first trench and a second trench, a first reflective electrode inside the first trench, a second reflective electrode inside the second trench, a first-first electrode on the interlayer insulating layer and connected to the first reflective electrode, a first-second electrode on the interlayer insulating layer and connected to the second reflective electrode, a second electrode on the first-first electrode and the first-second electrode, a first color filter on the second electrode to overlap the first-first electrode, and a second color filter on the second electrode to overlap the first-second electrode, wherein the interlayer insulating layer includes insulating layers, at least two of the insulating layers contain different materials, and at least one of the first trench or the second trench penetrates the insulating layers containing different materials of the interlayer insulating layer.

### CROSS-REFERENCE TO RELATED APPLICATION

This application claims priority from Korean Patent Application No. 10-2023-0120378 filed on Sep. 11, 2023 in the Korean Intellectual Property Office, and all the benefits accruing therefrom under 35 U.S.C. 119, the contents of which are incorporated by reference herein in its entirety.

### BACKGROUND

### 1. Technical Field

The present disclosure relates to a display device, and more particularly to a display device capable of differentiating a resonance distance according to a wavelength of light to be emitted from each pixel and a method for fabricating the same.

### 2. Description of the Related Art

A head mounted display (HMD) is an image display device that is worn on a user's head in the form of goggles or helmets to form a focus at a close distance in front of the user's eyes. The head mounted display can implement virtual reality (VR) or augmented reality (AR).

The head mounted display magnifies an image displayed on a small display device using a variety of lenses, and displays the magnified image. Therefore, the display device used for the head mounted display must provide high-resolution images, for example, images with a resolution of 3000 PPI (Pixels Per Inch) or more. For this purpose, an organic light emitting diode on silicon (OLEDoS), which is a high-resolution small organic light emitting display device, is used as the display device for the head mounted display. The OLEDoS is an image display device in which an organic light emitting diode (OLED) is arranged on a semiconductor substrate on which a complementary metal oxide semiconductor (CMOS) is arranged.

### SUMMARY

One of aspects of the present disclosure provides a display device capable of differentiating a resonance distance according to the wavelength of light to be emitted from each pixel and a method for fabricating the same.

According to an embodiment of the disclosure, a display device comprising: a substrate; an interlayer insulating layer disposed on the substrate and having a first trench and a second trench, wherein the first trench has a different depth from the second trench in a thickness direction; a first reflective electrode disposed inside the first trench; a second reflective electrode disposed inside the second trench; a first-first electrode disposed on the interlayer insulating layer and connected to the first reflective electrode on the interlayer insulating layer;; a first-second electrode disposed on the interlayer insulating layer and connected to the second reflective electrode; a second electrode disposed on the first-first electrode and the first-second electrode; a first color filter disposed on the second electrode to overlap the first-first electrode in the thickness direction; and a second color filter disposed on the second electrode to overlap the first-second electrode in the thickness direction, wherein the interlayer insulating layer includes a plurality of insulating layers, at least two of the plurality of insulating layers contain different materials, and at least one of the first trench or the second trench penetrates the plurality of insulating layers containing different materials of the interlayer insulating layer in the thickness direction.

In an embodiment, the number of the insulating layers penetrated by the first trench in the thickness direction is different from the number of the insulating layers penetrated by the second trench in the thickness direction.

In an embodiment, the interlayer insulating layer includes: a first insulating layer; and a second insulating layer disposed on the first insulating layer to be adjacent to the first insulating layer and containing a different material from the first insulating layer.

In an embodiment, the interlayer insulating layer includes a plurality of first insulating layers and a plurality of second insulating layers disposed alternately.

In an embodiment, the first reflective electrode is disposed along side and bottom walls of the first trench, and the second reflective electrode is disposed along side and bottom walls of the second trench.

In an embodiment, each of the first reflective electrode and the second reflective electrode has an U-shaped structure when viewed from a cross section.

In an embodiment, further comprising: a first intermediate insulating layer disposed between the first reflective electrode and the first-first electrode of the first trench; and a second intermediate insulating layer disposed between the second reflective electrode and the first-second electrode of the second trench.

In an embodiment, one portion of the first intermediate insulating layer is surrounded by the first reflective electrode, and the other portion of the first intermediate insulating layer is surrounded by the first-first electrode, and one portion of the second intermediate insulating layer is surrounded by the second reflective electrode, and the other portion of the second intermediate insulating layer is surrounded by the first-second electrode.

In an embodiment, a depth of the first intermediate insulating layer in the thickness direction is different from a depth of the second intermediate insulating layer in the thickness direction.

In an embodiment, a distance from a bottom surface of the second electrode to a bottom of the first reflective electrode, which is disposed at a bottommost portion of the first trench, is different from a distance from a bottom surface of the second electrode to a bottom of the second reflective electrode, which is disposed at a bottommost portion of the second trench.

In an embodiment, the first-first electrode is connected to a transistor on the substrate through at least a contact hole connected to the first trench in the thickness direction.

In an embodiment, the first-first electrode is connected to a transistor on the substrate through at least a contact hole penetrating the interlayer insulating layer in the thickness direction.

In an embodiment, further comprising an intermediate layer interposed between the first-first electrode and the first-second electrode and the second electrode.

In an embodiment, further comprising a pixel defining layer disposed between the first-first electrode and the first-second electrode to define emission areas having a first emission area and a second emission area, and the first-first electrode overlaps the first emission area in the thickness direction, and the first-second electrode overlaps the second emission area in the thickness direction.

According to an embodiment of the disclosure, a method for fabricating a display device, comprising: forming an interlayer insulating layer including a plurality of insulating layers on a substrate; forming a first trench and a second trench having different depths in the interlayer insulating layer; forming a reflective electrode disposed on side and bottom walls of the first trench and side and bottom walls of the second trench and disposed on the interlayer insulating layer; forming an intermediate insulating layer disposed on the reflective electrode; by removing the reflective electrode on the interlayer insulating layer and the intermediate insulating layer on the interlayer insulating layer, forming a first reflective electrode and a second reflective electrode disposed along the side and bottom walls of the first trench and the side and bottom walls of the second trench, respectively, and separated from each other, and forming a first intermediate insulating layer and a second intermediate insulating layer disposed inside the first trench and the second trench, respectively, and separated from each other; forming a first-first electrode disposed on the interlayer insulating layer and connected to the first reflective electrode and a first-second electrode disposed on the interlayer insulating layer and connected to the first reflective electrode; and forming a second electrode disposed on the first-first electrode and the first-second electrode, wherein at least two of the plurality of insulating layers contain different materials, and at least one of the first trench or the second trench penetrates the plurality of insulating layers containing different materials of the interlayer insulating layer in a thickness direction.

In an embodiment, the number of the insulating layers penetrated by the first trench is different from the number of the insulating layers penetrated by the second trench.

In an embodiment, the interlayer insulating layer includes: a first insulating layer; and a second insulating layer disposed on the first insulating layer to be adjacent to the first insulating layer, and containing a different material of the first insulating layer.

In an embodiment, the interlayer insulating layer includes a plurality of first insulating layers and a plurality of second insulating layers disposed alternately.

In an embodiment, each of the first reflective electrode and the second reflective electrode has an U-shaped structure when viewed from a cross section.

In an embodiment, a depth of the first intermediate insulating layer in the thickness direction is different from a depth of the second intermediate insulating layer in the thickness direction.

In an embodiment, a distance from a bottom surface of the second electrode to a bottom of the first reflective electrode, which is disposed at a bottommost portion of the first trench, is different from a distance from a bottom surface of the second electrode to a bottom of the second reflective electrode, which is disposed at a bottommost portion of the second trench.

In an embodiment, the removing of the reflective electrode and the intermediate insulating layer on the interlayer insulating layer is accomplished by chemical mechanical polishing.

In an embodiment, further comprising: after the forming the first-first electrode and the first-second electrode, forming a pixel defining layer disposed on edges of the first-first electrode and first-second electrode to define emission areas; and forming an intermediate layer disposed between the pixel defining layer and the second electrode.

According to the display device and the fabricating method of the present disclosure, the resonance distances of respective pixels can be adjusted to be different from each other by forming trenches of the respective pixels to have different depths. As a result, while the process steps are simplified, a micro-cavity (or a thin-film resonance) effect on light can be enhanced and/or optimized depending on the wavelength of the light to be emitted from each pixel and the resonance distance and/or resonance order corresponding thereto.

In addition, since the trenches of the different depths are formed by using a plurality of insulating layers having different etching ratios, the depths of the trenches of the respective pixels can be more accurately controlled.

The effects of the present disclosure are not limited to the above-described effects and other effects which are not described herein will become apparent to those skilled in the art from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exploded view showing a display device according to one embodiment;

FIG. 2 is a layout diagram illustrating an example of the display panel shown in FIG. 1;

FIG. 3 is a block diagram illustrating a display device according to one embodiment;

FIG. 4 is an equivalent circuit diagram of a first pixel according to one embodiment;

FIG. 5 is a layout view illustrating pixels of a display area according to one embodiment;

FIG. 6 is a cross-sectional view illustrating an example of the display device taken along line A-A′ of FIG. 5;

FIG. 7 is a perspective view illustrating a head mounted display device according to one embodiment;

FIG. 8 is an exploded view illustrating an example of the head mounted display device of FIG. 7;

FIG. 9 is a perspective view illustrating a head mounted display device according to one embodiment;

FIG. 10 is a cross-sectional view of a display device according to one embodiment;

FIG. 11 is a diagram for illustrating a connection relationship between an anode electrode and a transistor in a display device according to one embodiment;

FIG. 12 is a diagram for illustrating a connection relationship between an anode electrode and a transistor in a display device according to one embodiment;

FIGS. 13 to 22 are cross-sectional views illustrating a method for fabricating a display device according to one embodiment;

FIG. 23 is a cross-sectional view of a display device according to one embodiment; and

FIGS. 24 and 25 are cross-sectional views for illustrating a method for fabricating a display device according to one embodiment.

### DETAILED DESCRIPTION OF THE EMBODIMENTS

The present disclosure will now be described more fully hereinafter with reference to the accompanying drawings, in which preferred embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, embodiments will be described in detail with reference to the accompanying drawings.

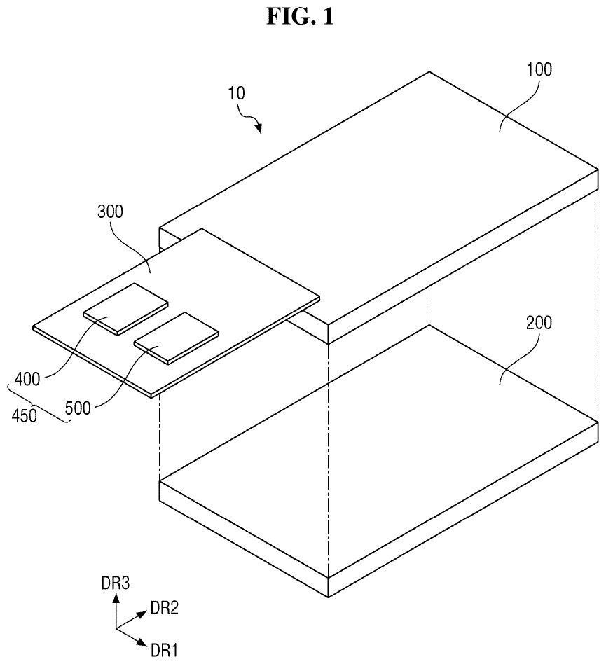

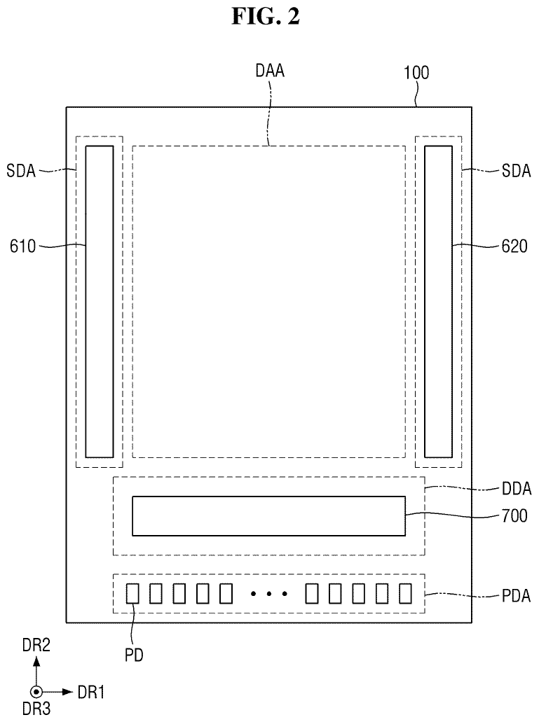

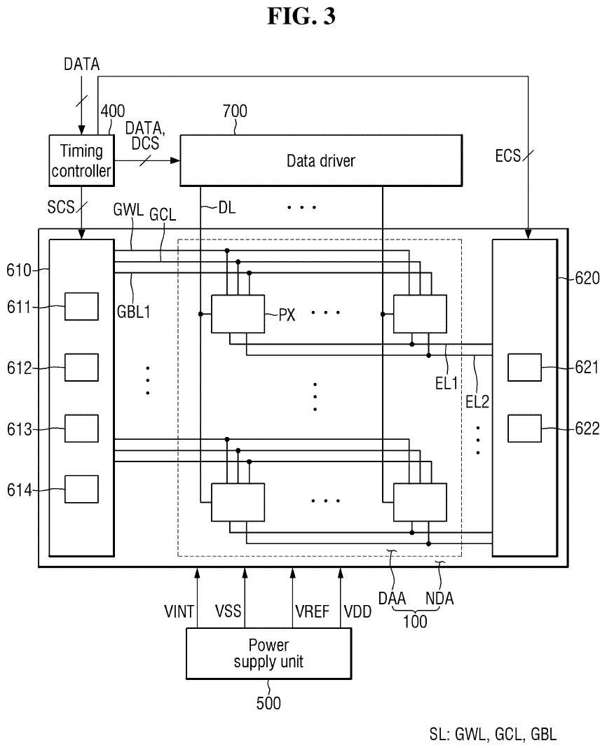

FIG. 1 is an exploded view showing a display device according to one embodiment. FIG. 2 is a layout diagram illustrating an example of the display panel shown in FIG. 1. FIG. 3 is a block diagram illustrating a display device according to one embodiment.

Referring to FIGS. 1 and 2, a display device 10 according to one embodiment is a device displaying a moving image or a still image. The display device 10 according to one embodiment is applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 is applied as a display unit of a television, a laptop, a monitor, a billboard, or an Internet-of-Things (IoT) device. Alternatively, the display device 10 is applied to a smart watch, a watch phone, a head mounted display (HMD) for implementing virtual reality and augmented reality, and the like.

The display device 10 according to one embodiment includes a display panel 100, a heat dissipation layer 200, a circuit board 300, and a driving circuit 450 including a timing control circuit 400 and a power supply circuit 500.

The display panel 100 has a planar shape similar to a quadrilateral shape. For example, the display panel 100 has a planar shape having a short side in a first direction DR1 and a long side in a second direction DR2 crossing the first direction DR1. In the display panel 100, a corner where a short side in the first direction DR1 and a long side in the second direction DR2 meet is right-angled or rounded with a predetermined curvature. The planar shape of the display panel 100 is not limited to a rectangular shape, and the display panel 10 has a shape of another polygonal shape, a circular shape, or an elliptical shape. The planar shape of the display device 10 conforms to the planar shape of the display panel 100, but the embodiment of the present disclosure is not limited thereto.

The display panel 100 includes a display area DAA used for displaying an image and a non-display area NDA not used for displaying an image as shown in FIG. 2.

The display area DAA includes a plurality of pixels PX, a plurality of scan lines SL, a plurality of emission control lines EL, and a plurality of data lines DL.

Each of the plurality of pixels PX includes a light emitting element that emits light. The plurality of pixels PX are arranged in a matrix form in the first direction DR1 and the second direction DR2. The plurality of scan lines SL and the plurality of emission control lines EL extend in the first direction DR1, while being arranged in the second direction DR2. The plurality of data lines DL extend in the second direction DR2, while being arranged in the first direction DR1.

The plurality of scan lines SL include a plurality of write scan lines GWL, a plurality of control scan lines GCL, and a plurality of bias scan lines GBL. The plurality of emission control lines EL include a plurality of first emission control lines EL1 and a plurality of second emission control lines EL2.

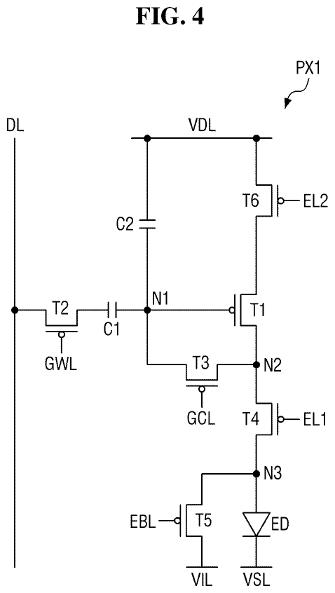

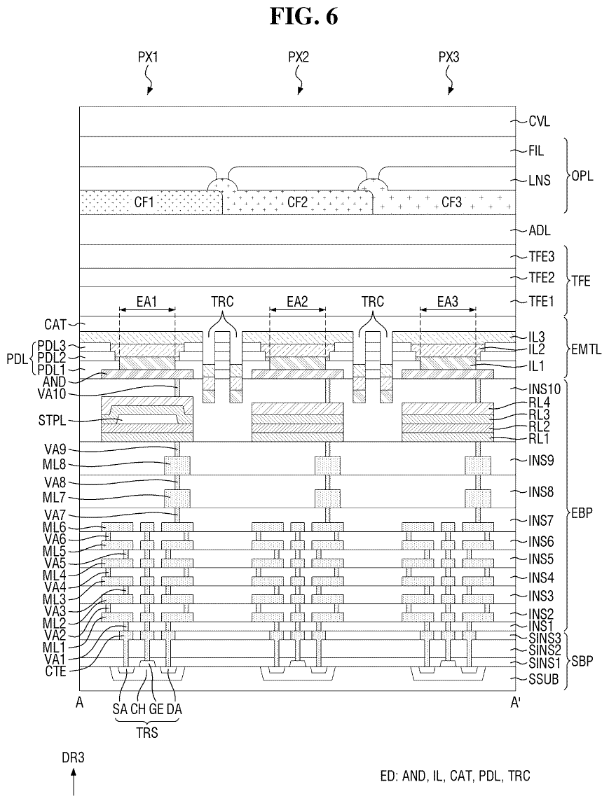

Each of a plurality of pixels PX includes a plurality of pixels PX1, PX2, and PX3. The plurality of pixels PX1, PX2, and PX3 include a plurality of pixel transistors as shown in FIG. 4, and the plurality of pixel transistors are formed through a semiconductor process and are disposed on a semiconductor substrate SSUB (see FIG. 6). For example, the plurality of pixel transistors are formed of a complementary metal oxide semiconductor (CMOS).

Each of the plurality of pixels PX1, PX2, and PX3 is connected to any one of the plurality of write scan lines GWL, any one of the plurality of control scan lines GCL, any one of the plurality of bias scan lines GBL, any one of the plurality of first emission control lines EL1, any one of the plurality of second emission control lines EL2, and any one of the plurality of data lines DL. Each of the plurality of pixels PX1, PX2, and PX3 receives a data voltage of the data line DL in response to a write scan signal of the write scan line GWL, and emits light from the light emitting element according to the data voltage.

The non-display area NDA includes a scan driving area SDA, a data driving area DDA, and a pad area PDA.

The scan driving area SDA is an area in which a scan driver 610 and an emission driver 620 are disposed. Although it is illustrated in FIG. 2 that the scan driver 610 is disposed on the left side of the display area DAA and the emission driver 620 is disposed on the right side of the display area DAA, the embodiment of the present disclosure is not limited thereto. For example, the scan driver 610 and the emission driver 620 are disposed on both the left side and the right side of the display area DAA.

The scan driver 610 includes a plurality of scan transistors, and the emission driver 620 includes a plurality of light emitting transistors. The plurality of scan transistors and the plurality of light emitting transistors are formed on the semiconductor substrate SSUB (see FIG. 6) through a semiconductor process. For example, the plurality of scan transistors and the plurality of light emitting transistors are formed of a CMOS.

The scan driver 610 includes a write scan signal output unit 611, a control scan signal output unit 612, and a bias scan signal output unit 613. Each of the write scan signal output unit 611, the control scan signal output unit 612, and the bias scan signal output unit 613 receive a scan timing control signal SCS from the timing control circuit 400. The write scan signal output unit 611 generates write scan signals according to the scan timing control signal SCS of the timing control circuit 400 and outputs the write scan signals sequentially to the write scan lines GWL. The control scan signal output unit 612 generates control scan signals in response to the scan timing control signal SCS and sequentially output the control scan signals to the control scan lines GCL. The bias scan signal output unit 613 generates bias scan signals according to the scan timing control signal SCS and output the bias scan signals sequentially to bias scan lines EBL.

The emission driver 620 includes a first emission control driver 621 and a second emission control driver 622. Each of the first emission control driver 621 and the second emission control driver 622 receives an emission timing control signal ECS from the timing control circuit 400. The first emission control driver 621 generates first emission control signals according to the emission timing control signal ECS and sequentially output the first emission control signals to first emission control lines EL1. The second emission control driver 622 generates second emission control signals according to the emission timing control signal ECS and sequentially output the second emission control signals to second emission control lines EL2.

The data driving area DDA is an area in which a data driver 700 is disposed. The data driver 700 includes a plurality of data transistors, and the plurality of data transistors are formed on the semiconductor substrate SSUB (see FIG. 6) through a semiconductor process. For example, the plurality of data transistors are formed of a CMOS.

The data driver 700 receives the digital video data DATA and the data timing control signal DCS from the timing control circuit 400. The data driver 700 converts the digital video data DATA into analog data voltages according to the data timing control signal DCS and outputs the analog data voltages to data lines DL. In this case, the pixels PX1, PX2, and PX3 are selected by the write scan signal of the scan driver 610, and data voltages are supplied to the selected pixels PX1, PX2, and PX3 accordingly.

The pad area PDA includes a plurality of pads PD arranged in the first direction DR1. Each of the plurality of pads PD is spaced apart each other and exposed without being covered by a cover layer CVL (see FIG. 6) and a polarizing plate (not shown).

The heat dissipation layer 200 overlaps the display panel 100 in a third direction DR3, which is the thickness direction of the display panel 100. The heat dissipation layer 200 is disposed on one surface of the display panel 100, for example, on the rear surface thereof. The heat dissipation layer 200 serves to dissipate heat generated from the display panel 100. The heat dissipation layer 200 includes a metal layer such as graphite, silver (Ag), copper (Cu), or aluminum (Al) having high thermal conductivity.

The circuit board 300 is electrically connected to a plurality of pads PD in a pad area PDA of the display panel 100 by using a conductive adhesive member such as an anisotropic conductive film. The circuit board 300 is a flexible printed circuit board with a flexible material, or a flexible film. Although the circuit board 300 is illustrated in FIG. 1 as being unfolded, the circuit board 300 can be bent. In this case, one end of the circuit board 300 is disposed on a bottom portion of the display panel 100. The one end of the circuit board 300 is connected to the plurality of pads PD of the pad area PDA of the display panel 100 by using a conductive adhesive member.

The timing control circuit 400 receives digital video data and timing signals inputted from the outside. The timing control circuit 400 generates the scan timing control signal SCS, the emission timing control signal ECS, and a data timing control signal DCS for controlling the display panel 100 in response to the timing signals. The timing control circuit 400 outputs the scan timing control signal SCS to the scan driver 610 and outputs the emission timing control signal ECS to the emission driver 620. The timing control circuit 400 outputs the digital video data and the data timing control signal DCS to the data driver 700.

The power supply circuit 500 generates a plurality of panel driving voltages according to a power voltage from the outside. For example, the power supply circuit 500 generates a first driving voltage VSS, a second driving voltage VDD, and a third driving voltage VINT and supplies the first driving voltage VSS, the second driving voltage VDD, and the third driving voltage VINT to the display panel 100 accordingly. Description of the first driving voltage VSS, the second driving voltage VDD, and the third driving voltage VINT is provided later with reference to FIG. 4.

Each of the timing control circuit 400 and the power supply circuit 500 is formed as an integrated circuit (IC) and attached to the circuit board 300. The scan timing control signal SCS, the emission timing control signal ECS, the digital video data DATA, and the data timing control signal DCS of the timing control circuit 400 is supplied to the display panel 100 through the circuit board 300. The first driving voltage VSS, the second driving voltage VDD, and the third driving voltage VINT of the power supply circuit 500 are supplied to the display panel 100 through the circuit board 300.

FIG. 4 is an equivalent circuit diagram of a first pixel according to one embodiment.

Referring to FIG. 4, the first pixel PX1 is connected to the write scan line GWL, the control scan line GCL, the bias scan line EBL, the first emission control line EL1, the second emission control line EL2, and the data line DL. In addition, the first pixel PX1 is connected to a first driving voltage line VSL to which the first driving voltage VSS corresponding to a low potential voltage is applied, a second driving voltage line VTL to which the second driving voltage VDD corresponding to a high potential voltage is applied, and a third driving voltage line VIL to which the third driving voltage VINT corresponding to an initialization voltage is applied. That is, the first driving voltage line VSL is a low potential voltage line, the second driving voltage line VDL is a high potential voltage line, and the third driving voltage line VIL is an initialization voltage line. In this case, the first driving voltage VSS is lower than the third driving voltage VINT, the second driving voltage VDD is higher than the third driving voltage VINT, and the second driving voltage VDD is higher than the first driving voltage VSS.

The first pixel PX1 includes a plurality of transistors T1, T2, T3, T4, T5, and T6, a light emitting element LE, a first capacitor C1, and a second capacitor C2.

The light emitting element ED emits light according to a driving current Ids (not shown herein) flowing through the channel of the first transistor T1. A light emission amount of the light emitting element ED is proportional to the driving current Ids. The light emitting element ED is disposed between the fourth transistor T4 and the first driving voltage line VSL. The first electrode of the light emitting element ED is connected to the drain electrode of the fourth transistor T4, and the second electrode thereof is connected to the first driving voltage line VSL. The first electrode of the light emitting element ED is an anode electrode, and the second electrode of the light emitting element ED is a cathode electrode. The light emitting element ED is an organic light emitting diode including a first electrode, a second electrode, and an organic light emitting layer disposed between the first electrode and the second electrode, but the embodiment of the present disclosure is not limited thereto. For example, the light emitting element ED is an inorganic light emitting element including a first electrode, a second electrode, and an inorganic semiconductor disposed between the first electrode and the second electrode, in which case the light emitting element ED is a micro light emitting diode.

The first transistor T1 includes a gate electrode connected to the first node N1, a source electrode connected to the drain electrode of the sixth transistor T6, and a drain electrode connected to a second node N2. The first transistor T1 is a driving transistor that controls a source-drain current Ids (hereinafter referred to as the “driving current”) flowing between the source electrode and the drain electrode thereof according to a voltage applied to the gate electrode thereof.

The second transistor T2 is disposed between the first capacitor C1 and the data line DL. The second transistor T2 includes a gate electrode connected to the write scan line GWL, a source electrode connected to the data line DL, and a drain electrode connected to the one electrode of the first capacitor C1. The second transistor T2 is turned on by the write scan signal of the write scan line GWL to connect the one electrode of the first capacitor C1 to the data line DL. Accordingly, the data voltage of the data line DL is applied to the one electrode of the first capacitor C1.

The third transistor T3 is disposed between the first node N1 and the second node N2. The third transistor T3 includes a gate electrode connected to the write control line GCL, a source electrode connected to the second node N2, and a drain electrode connected to the first node N1. The third transistor T3 is turned on by the write control signal of the write control line GCL to connect the first node N1 to the second node N2. For this reason, since the gate electrode and the source electrode of the first transistor T1 are connected, the first transistor T1 operates as a diode.

The fourth transistor T4 is disposed between the second node N2 and a third node N3. The fourth transistor T4 includes a gate electrode connected to the first emission control line EL1, a source electrode connected to the second node N2, and a drain electrode connected to the third node N3.

The fourth transistor T4 is turned on by the first emission control signal of the first emission control line EL1 to connect the second node N2 to the third node N3. Accordingly, the driving current of the first transistor T1 is supplied to the light emitting element ED.

The fifth transistor T5 is disposed between the third node N3 and the third driving voltage line VIL. The fifth transistor T5 includes a gate electrode connected to the bias scan line EBL, a source electrode connected to the third node N3, and a drain electrode connected to the third driving voltage line VIL. The fifth transistor T5 is turned on by the bias scan signal of the bias scan line EBL to connect the third node N3 to the third driving voltage line VIL. Accordingly, the third driving voltage VINT of the third driving voltage line VIL is applied to the first electrode of the light emitting element ED.

The sixth transistor T6 is disposed between the source electrode of the first transistor T1 and the second driving voltage line VDL. The sixth transistor T6 includes a gate electrode connected to the second emission control line EL2, a source electrode connected to the second driving voltage line VDL, and a drain electrode connected to the source electrode of the first transistor T1. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL is applied to the source electrode of the first transistor T1.

The first capacitor C1 is disposed between the first node N1 and the drain electrode of the second transistor T2. The first capacitor C1 includes a first electrode connected to the drain electrode of the second transistor T2 and a second electrode connected to the first node N1.

The second capacitor C2 is disposed between the gate electrode of the first transistor T1 and the second driving voltage line VDL. The second capacitor C2 includes a first electrode connected to the gate electrode of the first transistor T1 and a second electrode connected to the second driving voltage line VDL.

The first node N1 is a junction disposed between the gate electrode of the first transistor T1, the drain electrode of the third transistor T3, the second electrode of the first capacitor C1, and the first electrode of the second capacitor C2. The second node N2 is a junction disposed between the drain electrode of the first transistor T1, the source electrode of the third transistor T3, and the source electrode of the fourth transistor T4. The third node N3 is a junction disposed between the drain electrode of the fourth transistor T4, the source electrode of the fifth transistor T5, and the first electrode of the light emitting element ED.

Each of the first to sixth transistors T1 to T6 is a metal-oxide-semiconductor field effect transistor (MOSFET). For example, each of the first to sixth transistors T1 to T6 is a P-type MOSFET, but the embodiment of the present disclosure is not limited thereto. Each of the first to sixth transistors T1 to T6 is an N-type MOSFET. Alternatively, some of the first to sixth transistors T1 to T6 are P-type MOSFETs, and the remaining transistors are an N-type MOSFET.

Although it is illustrated in FIG. 4 that the first pixel PX1 includes the six transistors T1 to T6 and the two capacitors C1 and C2, it should be noted that the equivalent circuit diagram of the first pixel PX1 is not limited to the example shown in FIG. 4. For example, the number of the transistors and the number of the capacitors of the first pixel PX1 are not limited to the example shown in FIG. 4.

In addition, the equivalent circuit diagram of the second pixel PX2 and the equivalent circuit diagram of the third pixel PX3 are substantially the same as the equivalent circuit diagram of the first pixel PX1 described in conjunction with FIG. 4. Thus, in the present disclosure, description of the equivalent circuit diagram of the second pixel PX2 and the equivalent circuit diagram of the third pixel PX3 are omitted.

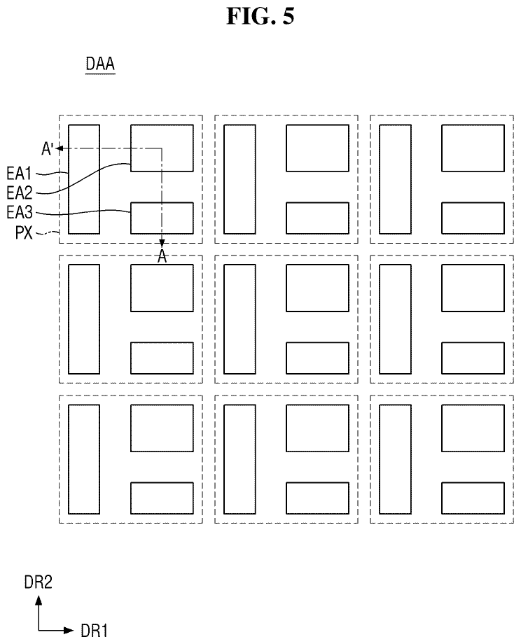

FIG. 5 is a layout view illustrating pixels of a display area according to one embodiment.

Referring to FIG. 5, each of the plurality of pixels PX includes a first emission area EA1 as an emission area of the first pixel PX1, a second emission area EA2 as an emission area of the second pixel PX2, and a third emission area EA3 as an emission area of the third pixel PX3.

Each of the first emission area EA1, the second emission area EA2, and the third emission area EA3 has, in plan view, a quadrilateral shape such as a rectangle, a square, or a diamond. For example, the first emission area EA1 has a rectangular shape, in plan view, having a short side in the first direction DR1 and a long side in the second direction DR2. In addition, each of the second emission area EA2 and the third emission area EA3 has a rectangular shape, in plan view, having a long side in the first direction DR1 and a short side in the second direction DR2.

The length of the first emission area EA1 in the first direction DR1 is smaller than lengths of the second emission area EA2 and the third emission area EA3 in the first direction DR1. In addition, the length of the second emission area EA2 and the length of the third emission area EA3 in the first direction DR1 are substantially the same.

The length of the first emission area EA1 in the second direction DR2 is larger than the sum of the length of the second emission area EA2 in the second direction DR2 and the length of third emission areas EA3 in the second direction DR2. The length of the second emission area EA2 in the second direction DR2 is larger than the length of the third emission area EA3 in the second direction DR2.

Although it is illustrated in FIG. 5 that each of the first emission area EA1, the second emission area EA2, and the third emission area EA3 has a rectangular shape in plan view, the embodiment of the present disclosure is not limited thereto. For example, each of the first emission area EA1, the second emission area EA2, and the third emission area EA3 has a polygonal shape other than a quadrilateral shape, a circular shape, or an elliptical shape in plan view.

In each of the plurality of pixels PX, the first emission area EA1 is disposed adjacent to the second emission area EA2 and the third emission area EA3 along the first direction DR1. In addition, the second emission area EA2 and the third emission area EA3 are adjacent to each other along the second direction DR2. In this example, the area of the first emission area EA1, the area of the second emission area EA2, and the area of the third emission area EA3 are different.

The first emission area EA1 emits light of a first color, the second emission area EA2 emits light of a second color, and the third emission area EA3 emits light of a third color. Here, the first color light has a blue wavelength band, the second color light has a green wavelength band, and the third color light has a red wavelength band. For example, the blue wavelength band has a main peak wavelength in the range of about 370 nm to about 460 nm, the green wavelength band has a main peak wavelength in the range of about 480 nm to about 560 nm, and the red wavelength band has a main peak wavelength in the range of about 600 nm to about 750 nm.

It is exemplified in FIG. 5 that each of the plurality of pixels PX includes three emission areas EA1, EA2, and EA3, but the embodiment of the present disclosure is not limited thereto. That is, each of the plurality of pixels PX includes less than three or more three emission areas.

In addition, the layout of the emission areas of the plurality of pixels PX is not limited to that illustrated in FIG. 5. For example, the emission areas of the plurality of pixels PX are arranged in a stripe structure in which the emission areas are arranged in the first direction DR1, a PenTile® structure in which the emission areas are arranged in a diamond shape, or a hexagonal structure in which the emission areas having, in plan view, a hexagonal shape are arranged side by side.

FIG. 6 is a cross-sectional view illustrating an example of the display device taken along line A-A′ of FIG. 5.

Referring to FIG. 6, the display panel 100 includes a semiconductor backplane SBP, a light emitting element backplane EBP, a light emitting element layer EMTL, an encapsulation layer TFE, an optical layer OPL, a cover layer CVL, and a polarizing plate (not shown).

The semiconductor backplane SBP includes the semiconductor substrate SSUB including a plurality of pixel transistors TRS, a plurality of semiconductor insulating layers SINS1, SINS2, SINS3 covering the plurality of pixel transistors TRS, and a plurality of contact terminals CTE electrically connected to the plurality of pixel transistors TRS, respectively. The plurality of pixel transistors TRS are the first to sixth transistors T1 to T6 described with reference to FIG. 4.

The semiconductor substrate SSUB is a silicon substrate, a germanium substrate, or a silicon-germanium substrate. The semiconductor substrate SSUB is a substrate doped with a first type impurity. A plurality of well regions are disposed on the top surface of the semiconductor substrate SSUB. The plurality of well regions are regions doped with a second type impurity. The second type impurity is different from the aforementioned first type impurity. For example, when the first type impurity is a p-type impurity, the second type impurity is an n-type impurity. Alternatively, when the first type impurity is an n-type impurity, the second type impurity is a p-type impurity.

Each of the plurality of well regions includes a source region SA corresponding to the source electrode of the pixel transistor TRS, a drain region DA corresponding to the drain electrode thereof, and a channel region CH disposed between the source region SA and the drain region DA.

Each of the source region SA and the drain region DA is a region doped with the first type impurity. A gate electrode GE of the pixel transistor TRS overlaps the well region in the third direction DR3. The channel region CH overlaps the gate electrode GE in the third direction DR3. The source region SA is disposed on one side of the gate electrode GE, and the drain region SA is disposed on the other side of the gate electrode GE.

Each of the plurality of well regions further includes a first low-concentration impurity region disposed between the channel region CH and the source region SA and a second low-concentration impurity region disposed between the channel region CH and the drain region DA. The first low-concentration impurity region LDD1 is a region having an impurity concentration lower than that of the source region SA. The second low-concentration impurity region is a region having an impurity concentration lower than that of the drain region DA. The distance between the source region SA and the drain region DA increases due to the presence of the first low-concentration impurity region and the second low-concentration impurity region. Therefore, the length of the channel region CH of each of the pixel transistors TRS increases so that punch-through and hot carrier phenomena that can be caused by a short channel are prevented.

A first semiconductor insulating layer SINS1 is disposed on the semiconductor substrate SSUB, and a second semiconductor insulating layer SINS2 is disposed on the first semiconductor insulating layer SINS1. The first semiconductor insulating layer SINS1 is formed of silicon carbonitride (SiCN) or a silicon oxide (SiOx)-based inorganic layer, and the second semiconductor insulating layer SINS2 is formed of a silicon oxide (SiOx)-based inorganic layer, but the embodiment of the present disclosure is not limited thereto.

The plurality of contact terminals CTE are disposed on the second semiconductor insulating layer SINS2. Each of the plurality of contact terminals CTE is connected to the gate electrode GE, the source region SA, and the drain region DA of each of the pixel transistors TRS through contact holes penetrating the first semiconductor insulating layer SINS1 and the second semiconductor insulating layer INS2. The plurality of contact terminals CTE are formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating layer SINS3 is disposed on the second insulating layer SINS 2 and a side surface of each of the plurality of contact terminals CTE. The top surface of each of the plurality of contact terminals CTE is exposed without being covered by the third semiconductor insulating layer SINS3. The third semiconductor insulating layer SINS3 is formed of a silicon oxide (SiOx)-based inorganic layer, but the embodiment of the present disclosure is not limited thereto.

The semiconductor substrate SSUB is replaced with a glass substrate or a polymer resin substrate such as polyimide. That is, thin film transistors are disposed on the glass substrate or the polymer resin substrate. For example, the glass substrate is a rigid substrate that does not bend, and the polymer resin substrate is a flexible substrate which can be bent or curved.

The light emitting element backplane EBP includes first to eighth metal layers ML1 to ML8, reflective metal layers RL1 to RL4, a plurality of vias VA1 to VA10,, a plurality of interlayer insulating layers INS1 to INS10, and a step layer STPL.

The first to eighth metal layers ML1 to ML8 serve to connect the plurality of contact terminals CTE exposed from the semiconductor backplane SBP to implement the circuit of the first pixel PX1 as shown in FIG. 4. That is, the first to sixth transistors T1 to T6 are merely formed on the semiconductor backplane SBP, and the connection of the first to sixth transistors T1 to T6 and the first and second capacitors C1 and C2 is accomplished through the first to eighth metal layers ML1 to ML8. In addition, the connection between the drain region corresponding to the drain electrode of the fourth transistor T4, the source region corresponding to the source electrode of the fifth transistor T5, and the first electrode of the light emitting element ED is also accomplished through the first to eighth metal layers ML1 to ML8.

The first interlayer insulating layer INS1 is disposed on the semiconductor backplane SBP. Each of the first vias VA1 thoroughly penetrates the first interlayer insulating layer INS1 to be connected to the contact terminal CTE exposed from the semiconductor backplane SBP. Each of the first metal layers ML1 is disposed on the first interlayer insulating layer INS1 and is connected to the first via VA1.

The second interlayer insulating layer INS2 is disposed on the first interlayer insulating layer INS1 and the first metal layers ML1. Each of the second vias VA2 partially penetrates the second interlayer insulating layer INS2 and be connected to the exposed first metal layer ML1. Each of the second metal layers ML2 is disposed on the second interlayer insulating layer INS2 and is connected to the second via VA2.

The third interlayer insulating layer INS3 is disposed on the second interlayer insulating layer INS2 and the second metal layers ML2. Each of the third vias VA3 partially penetrates the third interlayer insulating layer INS3 and be connected to the exposed second metal layer ML2. Each of the third metal layers ML3 is disposed on the third interlayer insulating layer INS3 and is connected to the third via VA3.

A fourth interlayer insulating layer INS4 is disposed on the third interlayer insulating layer INS3 and the third metal layers ML3. Each of the fourth vias VA4 partially penetrates the fourth interlayer insulating layer INS4 and be connected to the exposed third metal layer ML3. Each of fourth metal layers ML4 is disposed on the fourth interlayer insulating layer INS4 and is connected to the fourth via VA4.

A fifth interlayer insulating layer INS5 is disposed on the fourth interlayer insulating layer INS4 and the fourth metal layers ML4. Each of the fifth vias VA5 penetrates the fifth interlayer insulating layer INS5 and be connected to the exposed fourth metal layer ML4. Each of fifth metal layers ML5 is disposed on the fifth interlayer insulating layer INS5 and is connected to the fifth via VA5.

A sixth interlayer insulating layer INS6 is disposed on the fifth interlayer insulating layer INS5 and the fifth metal layers ML5. Each of the sixth vias VA6 partially penetrates the sixth interlayer insulating layer INS6 and be connected to the exposed fifth metal layer ML5. Each of sixth metal layers ML6 is disposed on the sixth interlayer insulating layer INS6 and is connected to the sixth via VA6.

A seventh interlayer insulating layer INS7 is disposed on the sixth interlayer insulating layer INS6 and the sixth metal layers ML6. Each of the seventh vias VA7 partially penetrates the seventh interlayer insulating layer INS7 and be connected to the exposed sixth metal layer ML6. Each of seventh metal layers ML7 is disposed on the seventh interlayer insulating layer INS7 and is connected to the seventh via VA7.

An eighth interlayer insulating layer INS8 is disposed on the seventh interlayer insulating layer INS7 and the seventh metal layers ML7. Each of the eighth vias VA8 partially penetrates the eighth interlayer insulating layer INS8 and be connected to the exposed seventh metal layer ML7. Each of eighth metal layers ML8 is disposed on the eighth interlayer insulating layer INS8 and is connected to the eighth via VA8.

The first to eighth metal layers ML1 to ML8 and the first to eighth vias VA1 to VA8 are formed of substantially the same material. The first to eighth metal layers ML1 to ML8 and the first to eighth vias VA1 to VA8 are formed of any one of copper (Cu), aluminum (Al), tungsten (W), molybdenum (Mo), chromium (Cr), gold (Au), titanium (Ti), nickel (Ni), and neodymium (Nd), or an alloy including any one of them. First to eighth interlayer insulating layers INS1 to ILD8 are formed of a silicon oxide (SiOx)-based inorganic layer, but the embodiment of the present disclosure is not limited thereto.

The thicknesses of the first metal layer ML1, the second metal layer ML2, the third metal layer ML3, the fourth metal layer ML4, the fifth metal layer ML5, and the sixth metal layer ML6 in the third direction DR3 are larger than the thicknesses of the first via VA1, the second via VA2, the third via VA3, the fourth via VA4, the fifth via VA5, and the sixth via VA6 in the third direction DR3, respectively. The thickness of each of the second metal layer ML2, the third metal layer ML3, the fourth metal layer ML4, the fifth metal layer ML5, and the sixth metal layer ML6 in the third direction DR3 is larger than the thickness of the first metal layer ML1 in the third direction DR3. The thickness of the second metal layer ML2, the thickness of the third metal layer ML3, the thickness of the fourth metal layer ML4, the thickness of the fifth metal layer ML5, and the thickness of the sixth metal layer ML6 in the third direction DR3 is substantially the same. For example, the thickness of the first metal layer ML1 is approximately 1360 Å, the thickness of each of the second metal layer ML2, the third metal layer ML3, the fourth metal layer ML4, the fifth metal layer ML5, and the sixth metal layer ML6 is approximately 1440 Å, and the thickness of each of the first via VA1, the second via VA2, the third via VA3, the fourth via VA4, the fifth via VA5, and the sixth via VA6 is approximately 1150 Å, respectively.

The thicknesses the seventh metal layer ML7 and the eighth metal layer ML8 in the third direction DR3 are larger than the thicknesses of the first metal layer ML1, the second metal layer ML2, the third metal layer ML3, the fourth metal layer ML4, the fifth metal layer ML5, and the sixth metal layer ML6 in the third direction DR3. The thicknesses of the seventh metal layer ML7 and the eighth metal layer ML8 in the third direction DR3 are larger than the thicknesses of the seventh via VA7 and the eighth via VA8 in the third direction DR3, respectively. The thicknesses the seventh via VA7 and the eighth via VA8 are larger than the thicknesses of the first via VA1, the second via VA2, the third via VA3, the fourth via VA4, the fifth via VA5, and the sixth via VA6 in the third direction DR3, respectively. The thickness of the seventh metal layer ML7 and the thickness of the eighth metal layer ML8 in the third direction DR3 are substantially the same. For example, the thickness of each of the seventh metal layer ML7 and the eighth metal layer ML8 is approximately 9000 Å. The thickness of each of the seventh via VA7 and the eighth via VA8 is approximately 6000 Å.

A ninth interlayer insulating layer INS9 is disposed on the eighth interlayer insulating layer INS8 and the eighth metal layers ML8. The ninth insulating layer INS9 is formed of a silicon oxide (SiOx)-based inorganic layer, but the embodiment of the present disclosure is not limited thereto.

Each of the ninth vias VA9 partially penetrates the ninth interlayer insulating layer INS9 and be connected to the exposed eighth metal layer ML8. The ninth vias VA9 is formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VA9 in the third direction DR3 is approximately 16500 Å.

Each of the first reflective metal layers RL1 is disposed on the ninth interlayer insulating layer INS9 and is connected to the ninth via VA9. The first reflective metal layers RL1 are formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

Each of the second reflective metal layers RL2 is disposed on the first reflective metal layer RL1. The second reflective metal layers RL2 are formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective metal layers RL2 are made of titanium nitride (TiN).

In the first pixel PX1, the step layer STPL is disposed on the second reflective metal layer RL2. However, in this case, the step layer STPL is not disposed in each of the second pixel PX2 and the third pixel PX3. To reflect the light of the first color emitted from a first light emitting layer of the first pixel PX1, the thickness of the step layer STPL is to set in consideration of the wavelength of the light of the first color and the distance from the first light emitting layer to the fourth reflective metal layer RL4. The step layer STPL is formed of silicon carbonitride (SiCN) or a silicon oxide (SiOx)-based inorganic layer, but the embodiment of the present disclosure is not limited thereto. The thickness of the step layer STPL in the third direction DR3 is about 400 Å.

In the first pixel PX1, the third reflective metal layer RL3 is disposed on the second reflective metal layer RL2 and the step layer STPL. In this case, the step layer STPL is interposed between the second reflective layer RL2 and third reflective layer RL3. In the second pixel PX2 and the third pixel PX3, the third reflective metal layer RL3 is disposed on the second reflective metal layer RL2. The third reflective metal layers RL3 is formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

In another example, at least one of the first reflective metal layer RL1, the second reflective metal layer RL2, or the third reflective metal layer RL3 can be omitted.

Each of the fourth reflective metal layers RL4 is disposed on the third reflective metal layer RL3. The fourth reflective metal layers RL4 reflects light from first to third intermediate layers IL1, IL2, and IL3. The fourth reflective metal layers RL4 include a metal having high reflectivity to advantageously reflect the light. The fourth reflective metal layers RL4 are formed of aluminum (Al), a stacked structure (Ti/Al/Ti) of aluminum and titanium, a stacked structure (ITO/Al/ITO) of aluminum and ITO, an APC alloy, which is an alloy of silver (Ag), palladium (Pd), and copper (Cu), and a stacked structure (ITO/APC/ITO) of the APC alloy and ITO, but the embodiment of the present disclosure is not limited thereto. Each of the fourth reflective metal layers RL4 has a thickness of about 850 Å in the third direction DR3. In this case, each of the first reflective metal layers RL1, the second reflective metal layers RL2, the third reflective metal layers RL3, and the fourth reflective metal layers RL4 is sequentially overlapped each other in the third direction DR3.

A tenth interlayer insulating layer INS10 is disposed on the ninth interlayer insulating layer INS9 and the fourth reflective metal layers RL4. The tenth insulating layer INS10 is formed of a silicon oxide (SiOx)-based inorganic layer, but the embodiment of the present disclosure is not limited thereto.

Each of the tenth vias VA10 partially penetrates the tenth interlayer insulating layer INS10 and be connected to each of the exposed first to fourth reflective metal layers RL1 to RL4 The tenth vias VA10 are formed of any one of copper (Cu), aluminum (Al), tungsten (W), molybdenum (Mo), chromium (Cr), gold (Au), titanium (Ti), nickel (Ni), and neodymium (Nd), or an alloy including any one of them. Due to the presence of the step layer STPL, the thickness of the tenth via VA10 in the first pixel PX1 in the third direction DR3 is less than the thicknesses of the tenth vias VA10 in each of the second pixel PX2 and the third pixel PX3 in the third direction DR3. For example, the thickness of the tenth via VA10 in the first pixel PX1 is about 800 Å, and the thicknesses of the tenth vias VA10 in each of the second pixel PX2 and the third pixel PX3 are about 1200 Å.

The light emitting element layer EMTL is disposed on the light emitting element backplane EBP. The light emitting element layer EMTL includes the light emitting elements ED each having the first electrode AND, the intermediate layer IL, and the second electrode CAT, a pixel defining layer PDL, and a plurality of trenches TRC.

The first electrode AND of the light emitting element ED is disposed on the tenth interlayer insulating layer INS10 and connected to the tenth via VA10. The first electrode AND of the light emitting element ED is connected to the drain region DA or source region SA of the pixel transistor TRS through the tenth via VA10, the first to fourth reflective metal layers RL1 to RL4, the first to ninth vias VA1 to VA9, the first to eighth metal layers ML1 to ML8, and the contact terminal CTE. The first electrode AND of the light emitting element ED is formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of the light emitting element ED is titanium nitride (TiN).

The pixel defining layer PDL is disposed on a part of the first electrode AND of the light emitting element ED. The pixel defining layer PDL covers the edge of the first electrode AND of the light emitting element ED. The pixel defining layer PDL partitions the first emission areas EA1, the second emission areas EA2, and the third emission areas EA3. That is, the pixel defining layer PDL is interposed between the first emission area EA1 and the second emission area EA2, is interposed between the second emission area EA2 and the third emission area EA3, and is interposed between the third emission area EA3 and the first emission area EAL.

The first emission area EA1 is defined as an area in which the first electrode AND, the intermediate layer IL, and the second electrode CAT are sequentially stacked in the first pixel PX1 along the third direction DR3 to emit light. The second emission area EA2 is defined as an area in which the first electrode AND, the intermediate layer IL, and the second electrode CAT are sequentially stacked in the second pixel PX2 along the third direction DR3 to emit light. The third emission area EA3 is defined as an area in which the first electrode AND, the intermediate layer IL, and the second electrode CAT are sequentially stacked in the third pixel PX3 along the third direction DR3 to emit light.

The pixel defining layer PDL includes first to third pixel defining layers PDL1, PDL2, and PDL3. The first pixel defining layer PDL1 is disposed on the edge of the first electrode AND, the second pixel defining layer PDL2 is disposed on the first pixel defining layer PDL1, and the third pixel defining layer PDL3 is disposed on the second pixel defining layer PDL2. The first pixel defining layer PDL1, the second pixel defining layer PDL2, and the third pixel defining layer PDL3 are formed of a silicon oxide (SiOx)-based inorganic layer, but the embodiment of the present disclosure is not limited thereto. Each of the first pixel defining layer PDL1, the second pixel defining layer PDL2, and the third pixel defining layer PDL3 has a thickness of about 500 Å in the third direction DR3.

Each of the plurality of trenches TRC penetrates the first pixel defining layer PDL1, the second pixel defining layer PDL2, and the third pixel defining layer PDL3 in the third direction DR3. The tenth interlayer insulating layer INS10 is partially recessed at each of the plurality of trenches TRC.

At least one trench TRC is disposed between adjacent pixels PX1, PX2, and PX3. Although FIG. 6 illustrates that two trenches TRC are disposed between adjacent pixels PX1, PX2, and PX3, the embodiment of the present disclosure is not limited thereto. In another example, three or more trenches TRC are disposed between adjacent pixels PX1, PX2, and PX3.

The intermediate layer IL includes a first intermediate layer IL1, a second intermediate layer IL2, and a third intermediate layer IL3.

The intermediate layer IL has a tandem structure including the plurality of intermediate layers IL1, IL2, and IL3 that emit different lights. For example, the intermediate layer IL includes the first intermediate layer IL1 that emits light of the first color, the second intermediate layer IL2 that emits light of the second color, and the third intermediate layer IL3 that emits light of the third color. The first intermediate layer IL1, the second intermediate layer IL2, and the third intermediate layer IL3 are sequentially stacked in the third direction DR3.

The first intermediate layer IL1 has a structure in which a first hole transport layer, a first organic light emitting layer that emits light of the first color, and a first electron transport layer are sequentially stacked in the third direction DR3. The second intermediate layer IL2 has a structure in which a second hole transport layer, a second organic light emitting layer that emits light of the third color, and a second electron transport layer are sequentially stacked in the third direction DR3. The third intermediate layer IL3 has a structure in which a third hole transport layer, a third organic light emitting layer that emits light of the second color, and a third electron transport layer are sequentially stacked in the third direction DR3.

A first charge generation layer for supplying charges to the second intermediate layer IL2 and supplying electrons to the first intermediate layer IL1 is disposed between the first intermediate layer IL1 and the second intermediate layer IL2. A second charge generation layer for supplying charges to the third intermediate layer IL3 and supplying electrons to the second intermediate layer IL2 is disposed between the second intermediate layer IL2 and the third intermediate layer IL3.

The first intermediate layer IL1 is disposed on the first electrode AND and the pixel defining layer PDL and is disposed on the bottom surface of each trench TRC. Due to the trench TRC, the first intermediate layer IL1 is separated between adjacent pixels PX1, PX2, and PX3. The second intermediate layer IL2 is disposed on the first intermediate layer IL1. Due to the trench TRC, the second intermediate layer IL2 is separated between adjacent pixels PX1, PX2, and PX3. The third intermediate layer IL3 is disposed on the second intermediate layer IL2. Due to the trench TRC, the third intermediate layer IL3 is separated between adjacent pixels PX1, PX2, and PX3. In this case, in each trench TRC, the first to third intermediate layers IL1 to IL3 are sequentially stacked along the third direction DR3. That is, each of the plurality of trenches TRC is a structure for separating the first to third intermediate layers IL1, IL2, and IL3 of the light emitting element layer EMTL between adjacent pixels PX1, PX2, and PX3.

To stably separate the first to third intermediate layers IL1, IL2, and IL3 of the light emitting element layer EMTL between adjacent pixels PX1, PX2, and PX3, the height of each of the plurality of trenches TRC is greater than the height of the pixel defining layer PDL. The height of each of the plurality of trenches TRC refers to the length of each of the plurality of trenches TRC in the third direction DR3. The height of the pixel defining layer PDL refers to the length of the pixel defining layer PDL in the third direction DR3.

To cut off the first to third intermediate layers IL1, IL2, and IL3 of the light emitting element layer EMTL between the neighboring pixels PX1, PX2, and PX3, another structure exists instead of the trench TRC. For example, instead of the trench TRC, a reverse tapered partition wall is disposed on the pixel defining layer PDL.

The number of the intermediate layers IL1, IL2, and IL3 that emit different lights is not limited to that shown in FIG. 6. For example, the intermediate layer IL includes two intermediate layers. In this case, one of the two intermediate layers is substantially the same as the first intermediate layer IL1, and the other includes a second hole transport layer, a second organic light emitting layer, and a second electron transport layer. In this case, a charge generation layer for supplying electrons to one intermediate layer and supplying charges to the other intermediate layer is disposed between the two intermediate layers.

In addition, FIG. 6 illustrates that the first to third intermediate layers IL1, IL2, and IL3 are all disposed in the first emission area EA1, the second emission area EA2, and the third emission area EA3, but the embodiment of the present disclosure is not limited thereto. For example, the first intermediate layer IL1 is disposed in the first emission area EA1 and is not be disposed in the second emission area EA2 and the third emission area EA3. Furthermore, the second intermediate layer IL2 is disposed in the second emission area EA2 and is not be disposed in the first emission area EA1 and the third emission area EA3. Further, the third intermediate layer IL3 is disposed in the third emission area EA3 and is not be disposed in the first emission area EA1 and the second emission area EA2. In this case, first to third color filters CF1, CF2, and CF3 of the optical layer OPL can be omitted.

The second electrode CAT is disposed on the third intermediate layer IL3. The second electrode CAT is disposed on the third intermediate layer IL3 in each of the plurality of trenches TRC. The second electrode CAT is formed of a transparent conductive material (TCO) such as ITO or IZO that can transmit light or a semi-transmissive conductive material such as magnesium (Mg), silver (Ag), or an alloy of Mg and Ag. When the second electrode CAT is formed of a semi-transmissive conductive material, the light emission efficiency is improved in each of the first to third pixels PX1, PX2, and PX3 due to a micro-cavity effect.

The encapsulation layer TFE is disposed on the light emitting element layer EMTL. The encapsulation layer TFE includes at least one inorganic layer to prevent oxygen or moisture from permeating into the light emitting element layer EMTL. In addition, the encapsulation layer TFE includes at least one organic layer to protect the light emitting element layer EMTL from foreign substances such as dust. For example, the encapsulation layer TFE includes a first encapsulation inorganic layer TFE1, an encapsulation organic layer TFE2, and a second encapsulation inorganic layer TFE3.

The first encapsulation inorganic layer TFE1 is disposed on the second electrode CAT, the encapsulation organic layer TFE2 is disposed on the first encapsulation inorganic layer TFE1, and the second encapsulation inorganic layer TFE3 is disposed on the encapsulation organic layer TFE2. The first encapsulation inorganic layer TFE1 and the second encapsulation inorganic layer TFE3 are formed of multiple layers in which one or more inorganic layers of silicon nitride (SiNₓ), silicon oxynitride (SiON), silicon oxide (SiOₓ), titanium oxide (TiOₓ), and aluminum oxide (AlOₓ) layers are alternately stacked. The encapsulation organic layer TFE2 is a monomer. Alternatively, the encapsulation organic layer TFE2 is an organic layer such as acryl resin, epoxy resin, phenolic resin, polyamide resin, polyimide resin or the like.

An adhesive layer ADL is disposed on the encapsulation layer TFE for bonding the encapsulation layer TFE to the optical layer OPL. In this example, the adhesive layer ADL is a double-sided adhesive member. In addition, the adhesive layer ADL is a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 include the first to third color filters CF1, CF2, and CF3. The first to third color filters CF1, CF2, and CF3 are disposed on the adhesive layer ADL.

The first color filter CF1 overlaps the first emission area EA1 of the first pixel PX1. The first color filter CF1 transmits light of the first color, i.e., light of a blue wavelength band of approximately 370 nm to 460 nm. Thus, the first color filter CF1 transmits light of the first color among light emitted from the first emission area EAL.

The second color filter CF2 overlaps the second emission area EA2 of the second pixel PX2. The second color filter CF2 transmits light of the second color, i.e., light of a green wavelength band of approximately 480 nm to 560 nm. Thus, the second color filter CF2 transmits light of the second color among light emitted from the second emission area EA2.

The third color filter CF3 overlaps the third emission area EA3 of the third pixel PX3. The third color filter CF3 transmits light of the third color, i.e., light of a red wavelength band of approximately 600 nm to 750 nm. Thus, the third color filter CF3 transmits light of the third color among light emitted from the third emission area EA3.

The plurality of lenses LNS are disposed on the first color filter CF1, the second color filter CF2, and the third color filter CF3, respectively. Each of the plurality of lenses LNS has a structure for increasing a ratio of light directed to the front of the display device 10. Each of the plurality of lenses LNS has a cross-sectional shape that is convex in an upward direction.

The filling layer FIL is disposed on the plurality of lenses LNS. The filling layer FIL has a predetermined refractive index such that light travels in the third direction DR3 at an interface between the filling layer FIL and the plurality of lenses LNS. Further, the filling layer FIL is a planarization layer. The filling layer FIL is an organic layer such as acrylic resin, epoxy resin, phenolic resin, polyamide resin, or polyimide resin.

The cover layer CVL is disposed on the filling layer FIL. The cover layer CVL is a glass substrate or a polymer resin. When the cover layer CVL is a glass substrate, it is attached onto the filling layer FIL. In this case, the filling layer FIL serves to bond the cover layer CVL. In another case, when the cover layer CVL is a glass substrate, it serves as an encapsulation substrate. In still another case, when the cover layer CVL is a polymer resin, it is directly applied onto the filling layer FIL.

Although not shown herein, the polarizing plate is disposed on one surface of the cover layer CVL. The polarizing plate is a structure for preventing visibility degradation caused by reflection of external light. The polarizing plate includes a linear polarizing plate and a phase retardation film. For example, the phase retardation film is a λ/4 plate (quarter-wave plate), but the embodiment of the present disclosure is not limited thereto. However, when visibility degradation caused by reflection of external light is sufficiently overcome by the first to third color filters CF1, CF2, and CF3, the polarizing plate can be omitted.

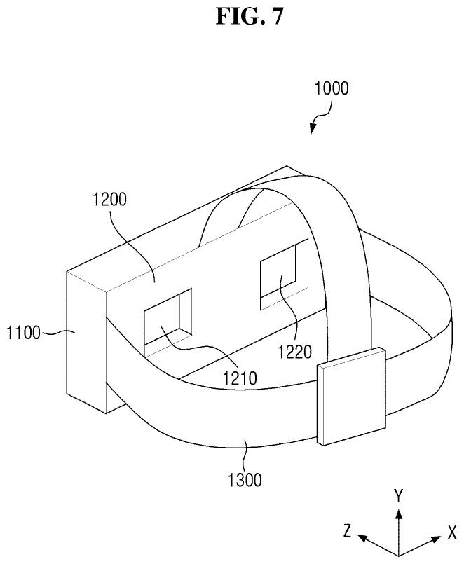

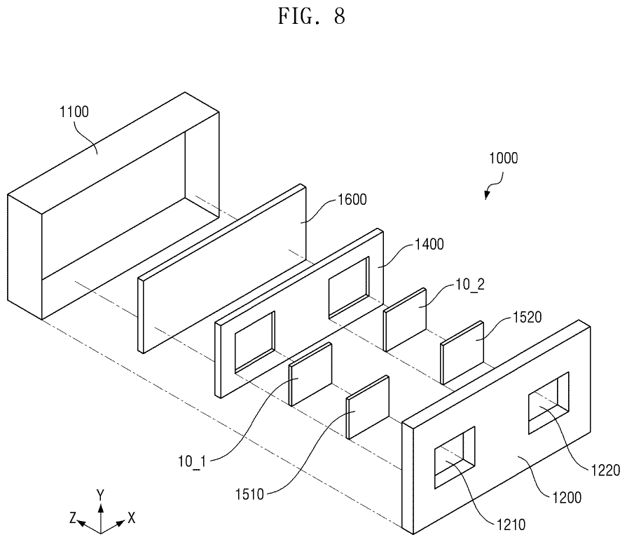

FIG. 7 is a perspective view illustrating a head mounted display device according to one embodiment. FIG. 8 is an exploded view illustrating an example of the head mounted display device of FIG. 7.

Referring to FIGS. 7 and 8, a head mounted display device 1000 according to one embodiment includes a first display device 10_1, a second display device 102, a display device housing 1100, a housing cover 1200, a first eyepiece 1210, a second eyepiece 1220, a head mounted band 1300, a middle frame 1400, a first optical member 1510, a second optical member 1520, a control circuit board 1600, and a connector (not shown herein).

The first display device 101 provides an image to one of the user's eye (i.e., left eye), and the second display device 10_2 provides an image to the other of the user's eye (i.e., right eye). Since each of the first display device 10_1 and the second display device 10_2 is substantially the same as the display device 10 described in conjunction with FIGS. 1 to 6, the description of the first display device 10_1 and the second display device 10_2 is omitted.

The first optical member 1510 is disposed between the first display device 10_1 and the first eyepiece 1210. The second optical member 1520 is disposed between the second display device 10_2 and the second eyepiece 1220. Each of the first optical member 1510 and the second optical member 1520 includes at least one convex lens.

The middle frame 1400 is disposed between the first and second display devices 10_1 and 10_2 and the control circuit board 1600. The middle frame 1400 supports and fix the first display device 101, the second display device 10_2, and the control circuit board 1600.

The control circuit board 1600 is disposed between the middle frame 1400 and the display device housing 1100. The control circuit board 1600 is connected to the first display device 10_1 and the second display device 10_2 through the connector. The control circuit board 1600 converts an image source inputted from the outside into digital video data DATA and transmits the digital video data DATA to the first display device 10_1 and the second display device 10_2 through the connector 1610.

The control circuit board 1600 transmits the digital video data DATA corresponding to a left-eye image optimized for the user's left eye to the first display device 10_1, and transmits the digital video data DATA corresponding to a right-eye image optimized for the user's right eye to the second display device 10_2. Alternatively, the control circuit board 1600 transmits the same digital video data DATA to the first display device 10_1 and the second display device 10_2.

The display device housing 1100 accommodates the first display device 10_1, the second display device 10_2, the middle frame 1400, the first optical member 1510, the second optical member 1520, the control circuit board 1600, and the connector. The housing cover 1200 is disposed to cover one open surface of the display device housing 1100. The housing cover 1200 includes the first eyepiece 1210 corresponding to the user's left eye and the second eyepiece 1220 corresponding to the user's right. FIGS. 7 and 8 illustrate that the first eyepiece 1210 and the second eyepiece 1220 are disposed separately, but the embodiment of the present disclosure is not limited thereto. The first eyepiece 1210 and the second eyepiece 1220 can be combined into one eyepiece.

The first eyepiece 1210 is aligned with the first display device 10_1 and the first optical member 1510 along a z-direction, and the second eyepiece 1220 is aligned with the second display device 10_2 and the second optical member 1520 along the z-direction. Therefore, the user views, through the first eyepiece 1210, the image of the first display device 10_1 magnified as a virtual image by the first optical member 1510, and views, through the second eyepiece 1220, the image of the second display device 10_2 magnified as a virtual image by the second optical member 1520.

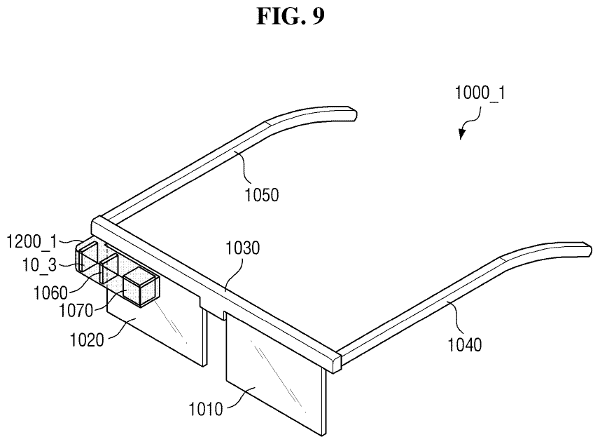

The head mounted band 1300 secures the display device housing 1100 to the user's head such that the first eyepiece 1210 and the second eyepiece 1220 of the housing cover 1200 remain disposed on the user's left and right eyes, respectively. When the display device housing 1100 is implemented to be light and compact, the head mounted display device 1000 is provided with, as shown in FIG. 9, an eyeglass frame instead of a head mounted band.

In addition, although not shown herein, the head mounted display device 1000 further includes a battery for supplying power, an external memory slot for accommodating an external memory, and an external connection port and a wireless communication module for receiving an image source. The external connection port is an universe serial bus (USB) terminal, a display port, or a high-definition multimedia interface (HDMI) terminal, and the wireless communication module is a 5G communication module, a 4G communication module, a Wi-Fi module, or a Bluetooth module.

FIG. 9 is a perspective view illustrating a head mounted display device according to one embodiment.

Referring to FIG. 9, a head mounted display device 1000_1 according to one embodiment is an eyeglasses-type display device in which a display device housing 1200_1 is implemented in a light and compact manner. The head mounted display device 1000_1 according to one embodiment includes a display device 103, a left eye lens 1010, a right eye lens 1020, a support frame 1030, temples 1040 and 1050, an optical member 1060, an optical path conversion member 1070, and the display device housing 1200_1.

The display device housing 12001 includes the display device 103, the optical member 1060, and the optical path conversion member 1070. The image displayed on the display device 10_3 is magnified by the optical member 1060 and is provided to the user's right eye through the right eye lens 1020 after the optical path thereof is converted by the optical path conversion member 1070. As a result, the user views an augmented reality image, through the right eye, in which a virtual image displayed on the display device 10_3 and a real image seen through the right eye lens 1020 are combined.

FIG. 9 illustrates that the display device housing 12001 is disposed at the end on the right side of the support frame 1030, but the embodiment of the present disclosure is not limited thereto. For example, the display device housing 1200_1 is disposed on the left end of the support frame 1030, and in this case, the image of the display device 10_3 is provided to the user's left eye. Alternatively, the display device housing 12001 is disposed on both the left and right ends of the support frame 1030, and in this case, the user views the image displayed on the display device 10_3 through both the left and right eyes.

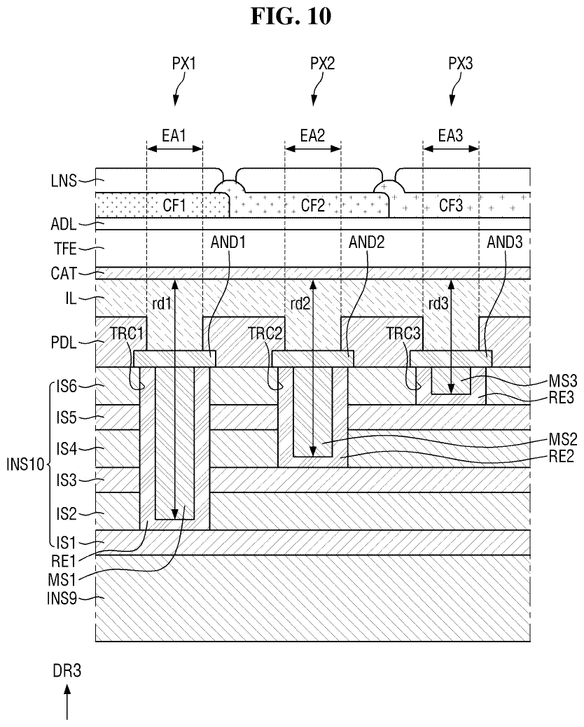

FIG. 10 is a cross-sectional view of a display device according to one embodiment.

Referring to FIG. 10, the ninth interlayer insulating layer INS9 is disposed on the semiconductor substrate SSUB (hereinafter, simply referred to as substrate SSUB). The ninth interlayer insulating layer INS9 is the same as the ninth interlayer insulating layer INS9 of FIG. 6.

The tenth interlayer insulating layer INS10 is disposed on the ninth interlayer insulating layer INS9. The tenth interlayer insulating layer INS10 includes a plurality of insulating layers having different etching ratios. For example, the tenth interlayer insulating layer INS10 includes a first insulating layer IS1, a second insulating layer IS2, a third insulating layer IS3, a fourth insulating layer IS4, a fifth insulating layer IS5, and a sixth insulating layer IS6 sequentially stacked on the ninth interlayer insulating layer INS9 along the third direction DR3 and having different etching ratios. In other words, the tenth interlayer insulating layer INS10 includes the first insulating layer IS1, the second insulating layer IS2, the third insulating layer IS3, the fourth insulating layer IS4, the fifth insulating layer IS5, and the sixth insulating layer IS6 sequentially stacked on the ninth interlayer insulating layer INS9 along the third direction DR3, and at least two of the insulating layers IS1 to IS6 contain different materials. For example, two insulating layers adjacent to each other in the third direction DR3 contain different materials.

Among the plurality of insulating layers included in the tenth interlayer insulating layer INS10, adjacent insulating layers have different etching ratios. For example, the first insulating layer IS1 and the second insulating layer IS2 have different etching ratios. In one embodiment, the first insulating layer IS1 is an insulating layer containing SiNx, and the second insulating layer IS2 is an insulating layer containing SiOx. As a specific example, SiNx and SiOx have an etching ratio of 1:5. In this case, SiOx is etched about 5 times more than SiNx for the same etchant.

Among the plurality of insulating layers included in the tenth interlayer insulating layer INS10, the insulating layers spaced apart from each other have the same etching ratio. For example, the first insulating layer IS1, the third insulating layer IS3, and the fifth insulating layer IS5 have the same etching ratio. In one embodiment, each of the first insulating layer IS1, the third insulating layer IS3, and the fifth insulating layer IS5 contain SiNx. In addition, in one embodiment, each of the second insulating layer IS2, the fourth insulating layer IS4, and the sixth insulating layer IS6 contains SiOx. For example, the first insulating layer IS1, the third insulating layer IS3, and the fifth insulating layer IS5 have the same material, and the second insulating layer IS2, the fourth insulating layer IS4, and the sixth insulating layer IS6 have the same material. In one embodiment, the interlayer insulating layer has a stacked structure in which insulating layers having different etching ratios are alternately disposed along the third direction DR3.

Meanwhile, the adjacent insulating layers have different thicknesses along the third direction DR3. For example, the second insulating layer IS2 has a thickness larger than that of the first insulating layer IS1 along the third direction DR3. In this case, the first insulating layer IS1, the third insulating layer IS3, and the fifth insulating layer IS5 have the same thickness along the third direction DR3. Further, the second insulating layer IS2, the fourth insulating layer IS4, and the sixth insulating layer IS6 have the same thickness along the third direction DR3. For example, each of the insulating layers (e.g., IS1, IS3, and IS5) containing SiNx has a thickness of approximately 100 Å to 500 Å, and each of the insulating layer (e.g., IS2, IS4, and IS6) containing SiOx has a thickness of approximately 300 Å to 1000 Å.

The tenth interlayer insulating layer INS10 has a plurality of trenches having different depths along the third direction DR3. For example, the tenth interlayer insulating layer INS10 has a first trench TRC1 disposed to correspond to the first pixel PX1 (or the first emission area EA1 of the first pixel PX1, or the first color filter CF1 of the first pixel PX1), a second trench TRC2 disposed to correspond to the second pixel PX2 (or the second emission area EA2 of the second pixel PX2, or the second color filter CF2 of the second pixel PX2), and a third trench TRC3 disposed to correspond to the third pixel PX3 (or the third emission area EA3 of the third pixel PX3, or the third color filter CF3 of the third pixel PX3). As shown in FIG. 10, the first to third trenches TRC1 to TRC3 have different depths along the third direction DR3. For example, the second trench TRC2 overlapping the second color filter CF2 has a depth larger than that of the third trench TRC3 overlapping the third color filter CF3 along the third direction DR3, and the first trench TRC1 overlapping the first color filter CF1 has a depth larger than that of the second trench TRC2 overlapping the second color filter CF2 along the third direction DR3. In other words, the depth of the second trench TRC2 along the third direction DR3is larger than the depth of the third trench TRC3 along the third direction DR3 and smaller than the depth of the first trench TRC1 along the third direction DR3.

As stated above, the number of the insulating layers penetrated by the first trench TRC1, the second trench TRC2, and the third trench TRC3 along the third direction DR3 are different so that the depths of the trenches TRC1 to TRC3 are different. For example, in one embodiment, the first trench TRC1 penetrates the sixth insulating layer IS6, the fifth insulating layer IS5, the fourth insulating layer IS4, the third insulating layer IS3, and the second insulating layer IS2. Meanwhile, although not shown, at least a part of the first insulating layer IS1 is removed by the first trench TRC1. The second trench TRC2 penetrates the sixth insulating layer IS6, the fifth insulating layer IS5, and the fourth insulating layer IS4. Meanwhile, although not shown, at least a part of the third insulating layer IS3 is removed by the second trench TRC2. The third trench TRC3 penetrates the sixth insulating layer IS6. Meanwhile, although not shown, at least a part of the fifth insulating layer IS5 is removed by the third trench TRC3.

In one embodiment, the first color filter CF1 is a red color filter, the second color filter CF2 is a green color filter, and the third color filter CF3 is a blue color filter. Alternatively, in one embodiment, the first color filter CF1 is a blue color filter, the second color filter CF2 is a green color filter, and the third color filter CF3 is a red color filter. Still alternatively, in one embodiment, the first color filter CF1 is a red color filter, the second color filter CF2 is a blue color filter, and the third color filter CF3 is a green color filter. Still alternatively, in one embodiment, the first color filter CF1 is a green color filter, the second color filter CF2 is a blue color filter, and the third color filter CF3 is a red color filter.

The red color filter transmits red light and blocks blue light and green light), the green color filter transmits green light and blocks red light and blue light, and the blue color filter transmits blue light and blocks red light and green light.

A first-first electrode AND1 (hereinafter, referred to as first anode electrode AND1), a first-second electrode AND2 (hereinafter, referred to as second anode electrode AND2), and a first-third electrode AND3 (hereinafter, referred to as third anode electrode AND3) are disposed on the tenth interlayer insulating layer INS10.

A first reflective electrode RE1, a second reflective electrode RE2, and a third reflective electrode RE3 are disposed in the first trench TRC1, the second trench TRC2, and the third trench TRC3 of the tenth interlayer insulating layer INS10, respectively. For example, the first reflective electrode RE1 is disposed along the inner walls of the first trench TRC1 including side and bottom walls, the second reflective electrode RE2 is disposed along the inner wall of the second trench TRC2 including side and bottom walls, and the third reflective electrode RE3 is disposed along the inner wall of the third trench TRC3 including side and bottom walls. In one embodiment, each of the first reflective electrode RE1, the second reflective electrode RE2, and the third reflective electrode RE3 has a U-shaped when viewed from a cross section. In one embodiment, each of the reflective electrodes RE1 to RE3 includes the first to fourth reflective metal layers RL1 to RL4 shown in FIG. 6 described above. For example, the first reflective electrode RE1 includes the first to fourth reflective metal layers RL1 to RL4, the second reflective electrode RE2 includes the first to fourth reflective metal layers RL1 to RL4, and the third reflective electrode RE3 includes the first to fourth reflective metal layers RL1 to RL4.

A first intermediate insulating layer MS1, a second intermediate insulating layer MS2, and a third intermediate insulating layer MS3 are disposed inside the first trench TRC1, the second trench TRC2, and the third trench TRC3, respectively. For example, the first intermediate insulating layer MS1 is disposed inside the first trench TRC1 to be surrounded by the first reflective electrode RE1 and the first anode electrode AND1. Similarly, the second intermediate insulating layer MS2 is disposed inside the second trench TRC2 to be surrounded by the second reflective electrode RE2 and the second anode electrode AND2, and the third intermediate insulating layer MS3 is disposed inside the third trench TRC3 to be surrounded by the third reflective electrode RE3 and the third anode electrode AND3.

The first intermediate insulating layer MS1, the second intermediate insulating layer MS2, and the third intermediate insulating layer MS3 have different thicknesses in the third direction DR3. For example, the second intermediate insulating layer MS2 has a thickness larger than that of the third intermediate insulating layer MS3 in the third direction DR3, and the first intermediate insulating layer MS1 has a thickness larger than that of the second intermediate insulating layer MS2 in the third direction DR3.

As described above, the first anode electrode AND1, the second anode electrode AND2, and the third anode electrode AND3 are disposed on the tenth interlayer insulating layer INS10. For example, the first anode electrode AND1 is disposed on the tenth interlayer insulating layer INS10 to overlap the first reflective electrode RE1 and the first intermediate insulating layer MS1 in the third direction DR3, the second anode electrode AND2 is disposed on the tenth interlayer insulating layer INS10 to overlap the second reflective electrode RE2 and the second intermediate insulating layer MS2 in the third direction DR3, and the third anode electrode AND3 is disposed on the tenth interlayer insulating layer INS10 to overlap the third reflective electrode RE3 and the third intermediate insulating layer MS3 in the third direction DR3.

The first anode electrode AND1 is in contact with the first reflective electrode RE1 and the first intermediate insulating layer MS1, the second anode electrode AND2 is in contact with the second reflective electrode RE2 and the second intermediate insulating layer MS2, and the third anode electrode AND3 is in contact with the third reflective electrode RE3 and the third intermediate insulating layer MS3. The first anode electrode AND1 is electrically connected to the first reflective electrode RE1, the second anode electrode AND2 is electrically connected to the second reflective electrode RE2, and the third anode electrode AND3 is electrically connected to the third reflective electrode RE3. In this case, each of the first to third anode electrodes AND1 to AND3 is the same as the first electrode AND illustrated in FIG. 6 above.

A pixel defining layer PDL defining the first emission area EA1, the second emission area EA2, and the third emission area EA3 is disposed on the tenth interlayer insulating layer INS10 and the first anode electrode AND1, the second anode electrode AND2, and the third anode electrode AND3. The pixel defining layer PDL is disposed between the intermediate layer IL and the first to third anode electrodes AND1 to AND3 to define the emission areas EA1 to EA3. In one embodiment, the pixel defining layer PDL includes the first pixel defining layer PDL1, the second pixel defining layer PDL2, and the third pixel defining layer PDL3 of FIG. 6. The first anode electrode AND1 overlaps the first emission area EA1, the second anode electrode AND2 overlaps the second emission area EA2, and the third anode electrode AND3 overlaps the third emission area EA3 in the third direction DR3.

The intermediate layer IL is disposed on the pixel defining layer PDL. The intermediate layer IL includes the first intermediate layer IL1, the second intermediate layer IL2, and the third intermediate layer IL3 of FIG. 6 above.

The second electrode CAT is disposed on the intermediate layer IL. The second electrode CAT of FIG. 10 is the same as the second electrode CAT of FIG. 6 above.

The encapsulation layer TFE is disposed on the second electrode CAT. The encapsulation layer TFE of FIG. 10 is the same as the encapsulation layer TFE of FIG. 6 above.

The adhesive layer ADL is disposed on the encapsulation layer TFE. The adhesive layer ADL of FIG. 10 is the same as the adhesive layer ADL of FIG. 6 above.

A color filter layer including the first color filter CF1, the second color filter CF2, and the third color filter CF3 are disposed on the adhesive layer ADL. For example, the first filter CF1 is correspondingly disposed on the first emission area EA1, the second filter CF2 is correspondingly disposed on the second emission area EA2, and the third filter CF3 is correspondingly disposed on the third emission area EA3. The first color filter CF1, the second color filter CF2, and the third color filter CF3 of FIG. 10 are the same as the first color filter CF1, the second color filter CF2, and the third color filter CF3 of FIG. 6 above, respectively.

The plurality of lenses LNS are disposed on the color filter layer (e.g., the first color filter CF1, the second color filter CF2, and the third color filter CF3). The plurality of lenses LNS of FIG. 10 are the same as the plurality of lenses LNS of FIG. 6 above.

As the first trench TRC1 overlapping the first color filter CF1, the second trench TRC2 overlapping the second color filter CF2, and the third trench TRC3 overlapping the third color filter CF3 have the different depths along the third direction DR3, distances from the bottom surface of the second electrode CAT to the bottom of the first reflective electrode RE1, from the bottom surface of the second electrode CAT to the bottom of the second reflective electrode RE2, and from the bottom surface of the second electrode CAT to the bottom of the third reflective electrode RE3 disposed in the trenches TRC1 to TRC3, respectively, along the third direction DR3 are different. For example, the distance from the bottom of the first reflective electrode RE1 to the bottom surface of the second electrode CAT is defined as a first resonance distance rd1, the distance from the bottom of the second reflective electrode RE2 to the bottom surface of the second electrode CAT is defined as a second resonance distance rd2, and the distance from the bottom of the third reflective electrode RE3 to the bottom surface of the second electrode CAT is defined as a third resonance distance rd3. In this case, the first resonance distance rd1, the second resonance distance rd2, and the third resonance distance rd3 are defined by the following Relational Expression 1. Here, each of the first resonance distance rd1, the second resonance distance rd2, and the third resonance distance rd3 means the length in the third direction DR3.

$$rd 1 > rd 2 > rd 3 \qquad < Relational Expression 1 >$$

Meanwhile, the bottom of a reflective electrode means a portion of the reflective electrode that is disposed at the bottommost portion of a trench to be in contact with an intermediate insulating layer. For example, the bottom of the first reflective electrode RE1 is a portion of the first reflective electrode RE1 that is disposed at the bottommost portion of the first trench TRC1 to be in contact with the first intermediate insulating layer MS1. In other words, the bottom of the first reflective electrode RE1 is a portion of the first reflective electrode RE1 that is in contact with one tip of an arrow defining the first resonance distance rd1 in FIG. 10. The same applies to the second resonance distance rd2 and the third resonance distance rd3.

In one embodiment, since the depths of the trenches of the pixels PX1 to PX3 are different, the resonance distances rd1, rd2, and rd3 from the reflective electrodes of the pixels PX1 to PX3 to the second electrode CAT, respectively, are different from each other. Accordingly, a micro-cavity (or a thin film resonance) effect on light is enhanced and/or optimized depending on the wavelength of the light to be emitted from each of the pixels PX1 to PX3 and the resonance distance and/or resonance order corresponding thereto. For example, light of the first color, light of the second color, and light of the third color are appropriately amplified in the first emission area EA1, the second emission area EA2, and the third emission area EA3, respectively. In one embodiment, the light of the first color emitted through the first emission area EA1 is red light corresponding to the first color filter CF1, the light of the second color emitted through the second emission area EA2 is green light corresponding to the second color filter CF2, and the light of the third color emitted through the third emission area EA3 is blue light corresponding to the third color filter CF3. In other words, the resonance distance rd2 of the second emission area EA2 through which the green light is emitted is larger than the resonance distance rd3 of the third emission area EA3 through which the blue light is emitted and is smaller than the resonance distance rd1 of the first emission area EA1 through which the red light is emitted.

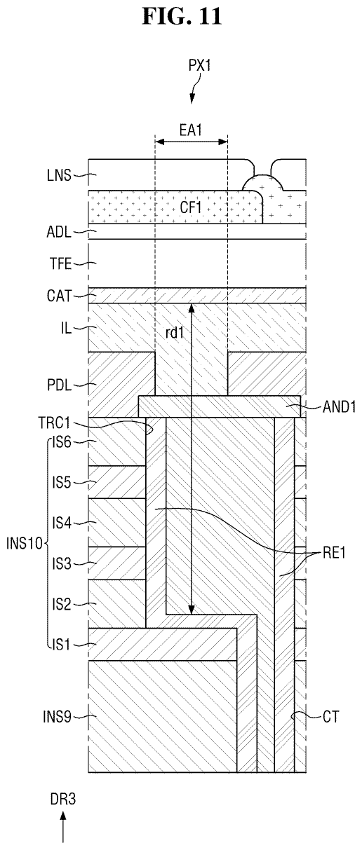

FIG. 11 is a diagram for illustrating a connection relationship between an anode electrode and a transistor in a display device according to one embodiment.

As illustrated in FIG. 11, the first anode electrode AND1 is connected to the drain region of a transistor (e.g., TRS of FIG. 6) through the first trench TRC1 in the first emission area EA1 and a contact hole CT in a non-emission area. Here, the contact hole CT is connected to the first trench TRC1. Furthermore, the contact hole CT penetrates the tenth interlayer insulating layer INS10 and the ninth interlayer insulating layer INS9 to expose the eighth metal layer ML8. The first anode electrode AND1 is connected to the eighth metal layer ML8 through the first reflective electrode RE1 in the first trench TRC1 and the first reflective electrode RE1 in the contact hole CT. As shown in FIG. 6, the eighth metal layer ML8 is connected to the drain region DA of the transistor TRS through the metal layers below.

The non-emission area refers to an area excluding the emission areas EA1, EA2, and EA3 in the display area.

Meanwhile, the second anode electrode AND2 and the third anode electrode AND3 are connected to corresponding transistors in the same manner as the first anode electrode AND1 as shown in FIG. 11.

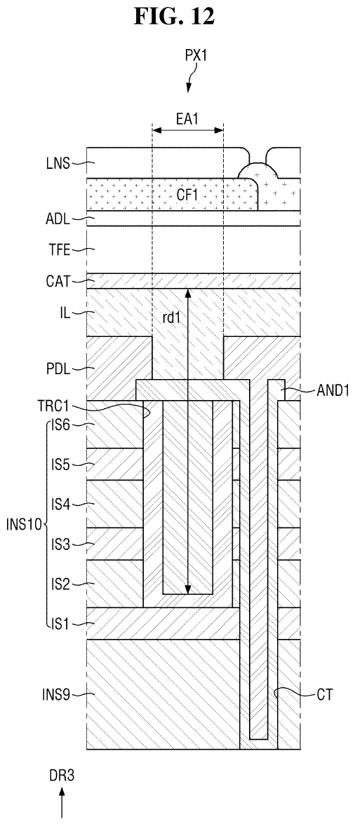

FIG. 12 is a diagram for illustrating a connection relationship between an anode electrode and a transistor in a display device according to one embodiment.

As shown in FIG. 12, the contact hole CT is disposed in a non-emission area to be adjacent to the first trench TRC1 which is disposed in the first emission area EAL. The contact hole CT penetrates the tenth interlayer insulating layer INS10 and the ninth interlayer insulating layer INS9 along the third direction DR3 to expose the eighth metal layer ML8. A portion of the first anode electrode AND1 in the non-emission area is disposed along the inner wall of the contact hole CT, and the other portion of the first anode electrode AND1 in the first emission area EA1 is disposed on the tenth interlayer insulating layer INS10. The first anode electrode AND1 is connected to the eighth metal layer ML8 through the contact hole CT. As shown in FIG. 6, the eighth metal layer ML8 is connected to the drain region DA of the corresponding transistor through the metal layers below.

The non-emission area refers to an area excluding the emission areas EA1 to EA3 in the display area.

Meanwhile, the second anode electrode AND2 and the third anode electrode AND3 are connected to the corresponding transistors in the same manner as the first anode electrode AND1 as illustrated in FIG. 12.

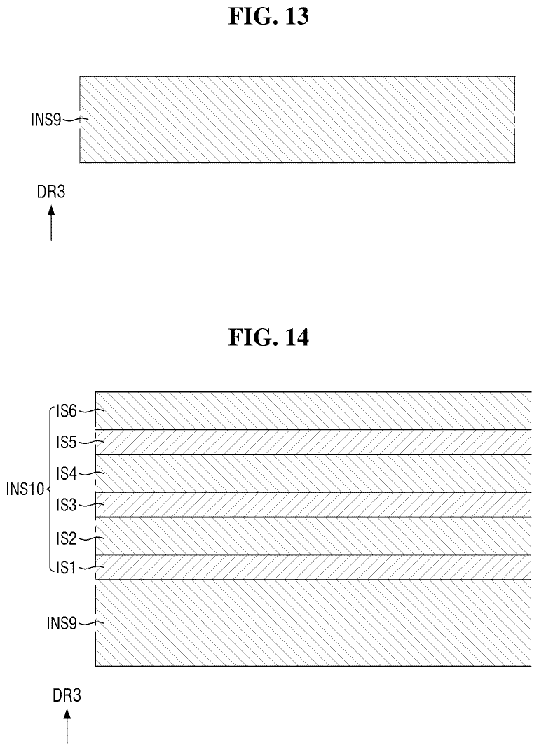

FIGS. 13 to 22 are cross-sectional views illustrating a method for fabricating a display device according to one embodiment.

As illustrated in FIG. 13, the ninth interlayer insulating layer INS9 is disposed on the substrate SSUB along the third direction DR3.

Subsequently, as illustrated in FIG. 14, the tenth interlayer insulating layer INS10 is disposed on the ninth interlayer insulating layer INS9 along the third direction DR3. For example, the first insulating layer IS1 is disposed on the ninth interlayer insulating layer INS9, the second insulating layer IS2 is disposed on the first insulating layer IS1, the third insulating layer IS3 is disposed on the second insulating layer IS2, the fourth insulating layer IS4 i disposed on the third insulating layer IS3, the fifth insulating layer IS5 is disposed on the fourth insulating layer IS4, and then the sixth insulating layer IS6 is disposed on the fifth insulating layer IS5.

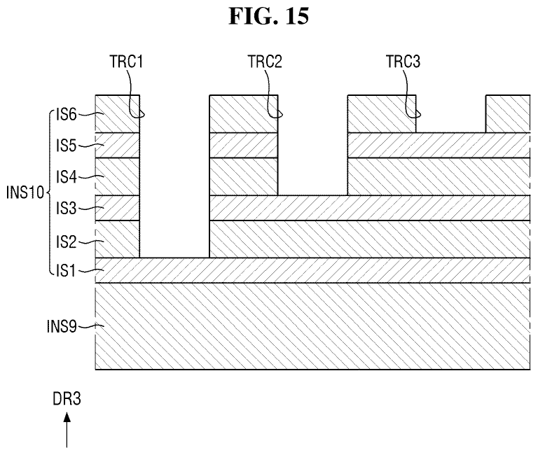

Thereafter, as illustrated in FIG. 15, the first trench TRC1, the second trench TRC2, and the third trench TRC3 having different depths along the third direction DR3 are formed. At this time, at least one of the first trench TRC1, the second trench TRC2, or the third trench TRC3 penetrates a plurality of insulating layers having different etching ratios.

In one embodiment, the first trench TRC1 penetrates the sixth insulating layer IS6, the fifth insulating layer IS5, the fourth insulating layer IS4, the third insulating layer IS3, and the second insulating layer IS2 along the third direction DR3. The first trench TRC1 is formed by sequentially etching the sixth insulating layer IS6, the fifth insulating layer IS5, the fourth insulating layer IS4, the third insulating layer IS3, and the second insulating layer IS2 through a first mask. Here, the etching process is a dry etching process. Since the adjacent insulating layers have different etching ratios, when one of the insulating layers is etched, the insulating layer under the one insulating layer functions as an etch stop layer during the etching process. For example, during the etching process for the sixth insulating layer IS6 in the course of forming the first trench TRC1, the fifth insulating layer IS5 under the sixth insulating layer S6 functions as the etching stop layer in the etching process. Although not shown herein, in the process of forming the first trench TRC1, at least a part of the first insulating layer IS1 is removed by the first trench TRC1.

The second trench TRC2 penetrates the sixth insulating layer IS6, the fifth insulating layer IS5, and the fourth insulating layer IS4 along the third direction DR3. The second trench TRC2 is formed by sequentially etching the sixth insulating layer IS6, the fifth insulating layer IS5, and the fourth insulating layer IS4 through a second mask along the third direction DR3. Here, the etching process is a dry etching process. Since the adjacent insulating layers have different etching ratios, when any one of the insulating layers is etched, the insulating layer under the one insulating layer functions as an etch stop layer during the etching process. Although not shown herein, in the process of forming the second trench TRC2, a part of the third insulating layer IS3 is removed by the second trench TRC2.

The third trench TRC3 penetrates the sixth insulating layer IS6 along the third direction DR3. The third trench TRC3 is formed by etching the sixth insulating layer IS6 through a third mask along the third direction DR3. Here, the etching process is a dry etching process. Since the adjacent insulating layers have different etching ratios, when any one of the insulating layers is etched, the insulating layer under the one insulating layer functions as an etch stop layer during the etching process. Although not shown herein, in the process of forming the third trench TRC3, a part of the fifth insulating layer IS5 is removed by the third trench TRC3.

In a method for fabricating a display device according to one embodiment, since the trenches TRC1 to TRC3 having different depths are formed using a plurality of insulating layers having different etching ratios, the depths of the trenches TRC1 to TRC3 of the pixels PX1 to PX3 are more accurately controlled.

Meanwhile, the contact hole CT of FIGS. 11 and 12 is further formed during or after the above-described process of forming the first trench TRC1, the second trench TRC2, and the third trench TRC3.

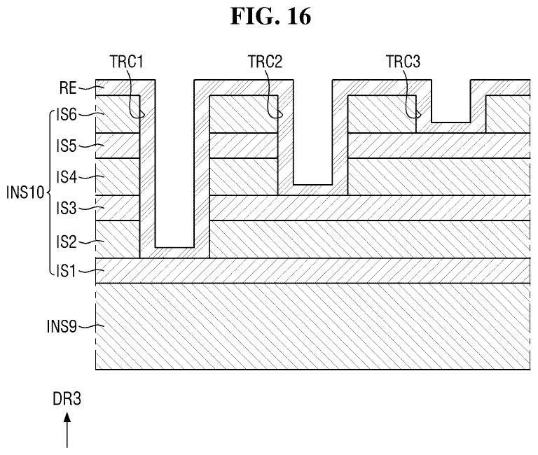

Next, as illustrated in FIG. 16, a reflective electrode RE is disposed on the tenth interlayer insulating layer INS10 having the first trench TRC1, the second trench TRC2, and the third trench TRC3. In this case, the reflective electrode RE is formed on the inner wall of the first trench TRC1, the inner wall of the second trench TRC2, and the inner wall of the third trench TRC3 as well as on the tenth interlayer insulating layer INS10. In other words, at least a part of the reflective electrode RE is formed along the inner wall of the first trench TRC1, the inner wall of the second trench TRC2, and the inner wall of the third trench TRC3, and the other part of the reflective electrode RE is formed on the tenth interlayer insulating layer INS10.

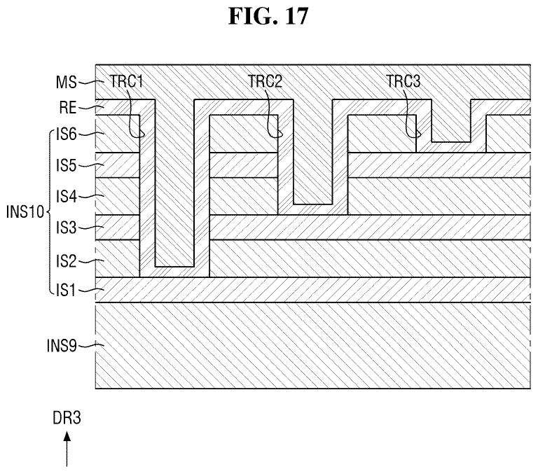

Thereafter, as shown in FIG. 17, the intermediate insulating layer MS is disposed on the reflective electrode RE. Here, the intermediate insulating layer MS is also disposed inside the first trench TRC1, the second trench TRC2, and the third trench TRC3.

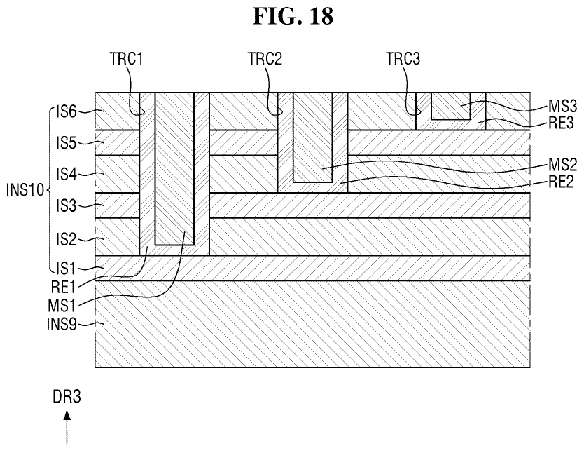

Then, the intermediate insulating layer MS and the reflective electrode RE are polished (or removed, or planarized) by a chemical mechanical polishing (CMP) method so that the first reflective electrode RE1, the second reflective electrode RE2, and the third reflective electrode RE3 are separately formed, and the first intermediate insulating layer MS1, the second intermediate insulating layer MS2, and the third intermediate insulating layer MS3 are separately formed as illustrated in FIG. 18. In other words, portions of the intermediate insulating layer MS and the reflective electrode RE located on the tenth interlayer insulating layer INS10 is selectively removed by the chemical mechanical polishing. In other words, the intermediate insulating layer MS and the reflective electrode RE are planarized to be level with the top surface of the sixth insulating layer IS6 of the tenth interlayer insulating layer INS10.

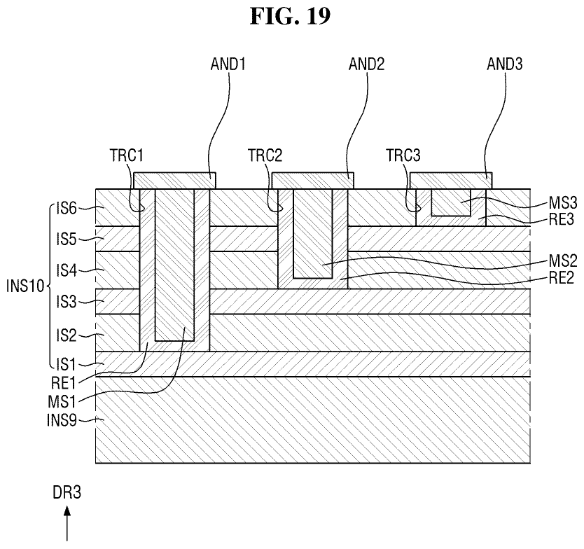

Thereafter, as illustrated in FIG. 19, the first anode electrode AND1, the second anode electrode AND2, and the third anode electrode AND3 are disposed on the tenth interlayer insulating layer INS10 (for example, the sixth insulating layer IS6 of the tenth interlayer insulating layer INS10). For example, the first anode electrode AND1 is formed on the tenth interlayer insulating layer INS10 to be in contact with the first reflective electrode RE1 and the first intermediate insulating layer MS1. Similarly, the second anode electrode AND2 is formed on the tenth interlayer insulating layer INS10 to be in contact with the second reflective electrode RE2 and the second intermediate insulating layer MS2, and the third anode electrode AND3 is formed on the tenth interlayer insulating layer INS10 to be in contact with the third reflective electrode RE3 and the third intermediate insulating layer MS3.

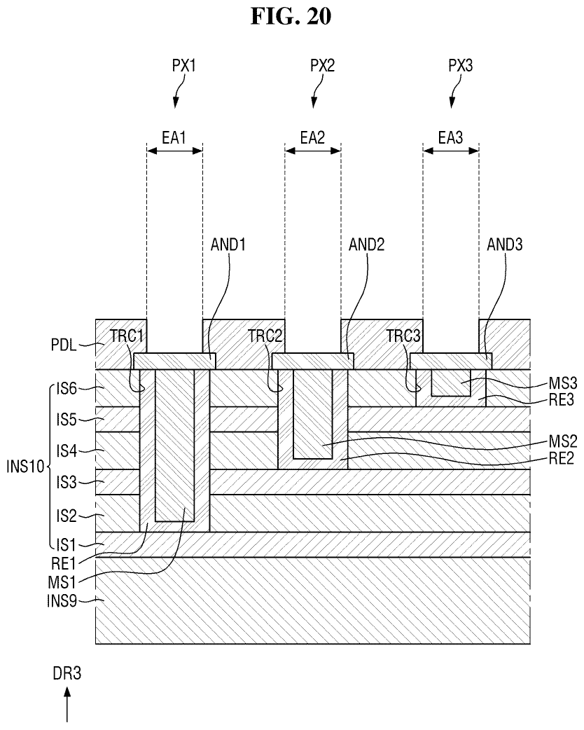

Subsequently, as illustrated in FIG. 20, the pixel defining layer PDL is formed to cover the edges of the first anode electrode AND1, the second anode electrode AND2, and the third anode electrode AND3. The first emission area EA1 of the first pixel PX1, the second emission area EA2 of the second pixel PX2, and the third emission area EA3 of the third pixel PX3 are defined by the pixel defining layer PDL. That is, the pixel defining layer PDL is disposed in a non-emission area.

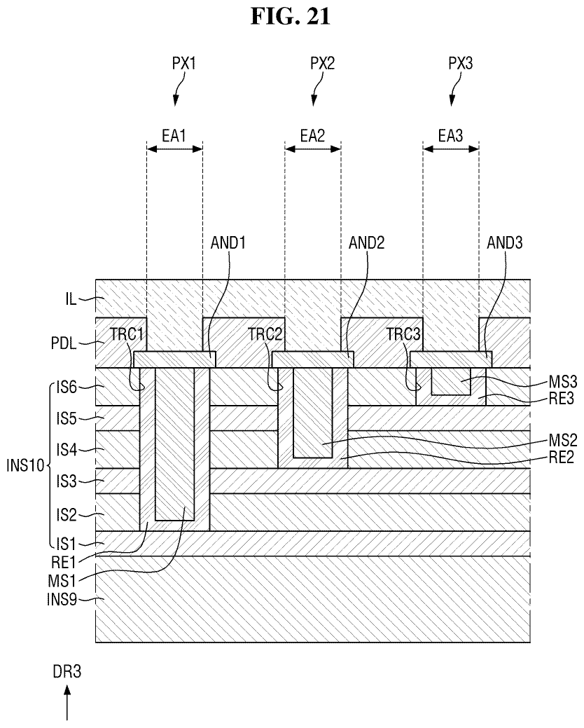

Next, as shown in FIG. 21, the intermediate layer IL is disposed on the pixel defining layer PDL and the first anode electrode AND1, the second anode electrode AND2, and the third anode electrode AND3.

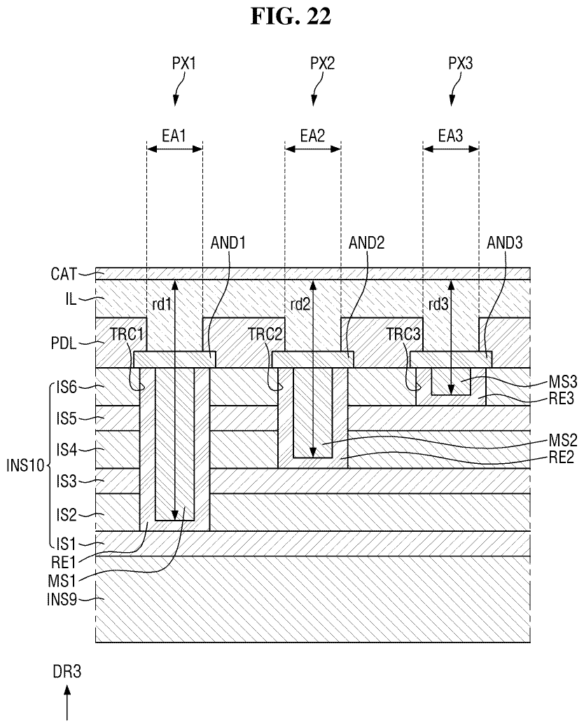

Thereafter, as shown in FIG. 22, the second electrode CAT is disposed on the intermediate layer IL.

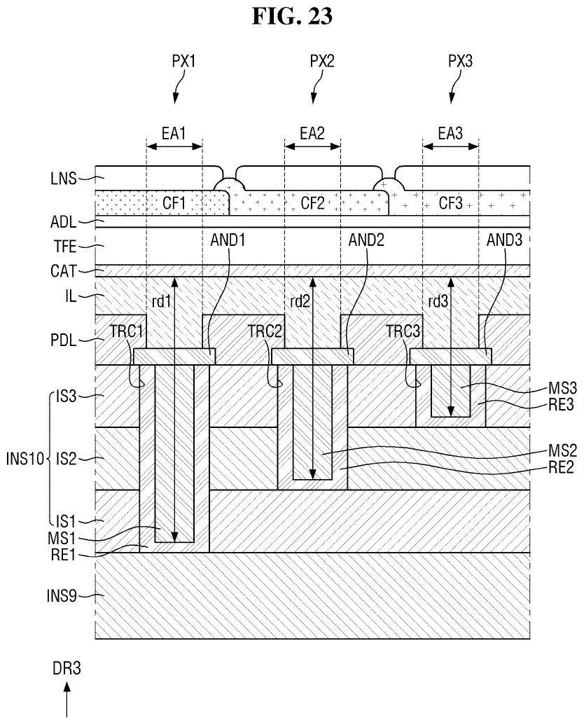

Next, as illustrated in FIG. 23, the encapsulation layer TFE, the adhesive layer ADL, the first color filter CF1, the second color filter CF2, the third color filter CF3, and the lenses LNS are formed on the second electrode CAT along the third direction DR3.

FIG. 23 is a cross-sectional view of a display device according to one embodiment.

The display device of FIG. 23 is different from the display device of FIG. 10 described above in that the number of the insulating layers belonging to the tenth interlayer insulating layers INS10 is different and the number of penetrating insulating layers for trenches, and the following description is mainly focus on this difference.

As shown in FIG. 23, the tenth interlayer insulating layer INS10 includes the first insulating layer IS1, the second insulating layer IS2, and the third insulating layer IS3 sequentially disposed on the ninth interlayer insulating layer INS9 along the third direction DR3.

Adjacent insulating layers among the first to third insulating layers IS1 to IS3 of the tenth interlayer insulating layer INS10 have different etching ratios. For example, the first insulating layer IS1 and the second insulating layer IS2 have different etching ratios. Meanwhile, the first insulating layer IS1 and the third insulating layer IS3 have the same etching ratio. For example, each of the first insulating layer IS1 and the third insulating layer IS3 contains SiNx, and the second insulating layer IS2 contains SiOx.

The first insulating layer IS1, the second insulating layer IS2, and the third insulating layer IS3 have the same thickness along the third direction DR3.

A plurality of trenches having different depths in the third direction DR3 are defined in the tenth interlayer insulating layer INS10. For example, the tenth interlayer insulating layer INS10 has the first trench TRC1 corresponding to the first pixel PX1 (or the first emission area EA1 of the first pixel PX1, or the first color filter CF1 of the first pixel PX1), the second trench TRC2 corresponding to the second pixel PX2 (or the second emission area EA2 of the second pixel PX2, or the second color filter CF2 of the second pixel PX2), and the third trench TRC3 corresponding to the third pixel PX3 (or the third emission area EA3 of the third pixel PX3, or the third color filter of the third pixel PX3). As shown in FIG. 23, the first to third trenches TRC1 to TRC3 have different depths in the third direction DR3. For example, the second trench TRC2 overlapping the second color filter CF2 has a depth larger than that of the third trench TRC3 overlapping the third color filter CF3, and the first trench TRC1 overlapping the first color filter CF1 has a depth larger than that of the second trench TRC2 overlapping the second color filter CF2. In other words, the depth of the second trench TRC2 is larger than the depth of the third trench TRC3 and smaller than the depth of the first trench TRC1. In one embodiment, the first trench TRC1 penetrates the third insulating layer IS3, the second insulating layer IS2, and the first insulating layer IS1 in the third direction DR3. Although not shown herein, a part of the ninth interlayer insulating layer INS9 is removed by the first trench TRC1. The second trench TRC2 penetrates the third insulating layer IS3 and the second insulating layer IS2 in the third direction DR3. Although not shown, a part of the first insulating layer IS1 is removed by the second trench TRC2. The third trench TRC3 penetrates the third insulating layer IS3 in the third direction DR3. Although not shown, a part of the second insulating layer IS2 is removed by the third trench TRC3.

In one embodiment, the first color filter CF1 is a red color filter, the second color filter CF2 is a green color filter, and the third color filter CF3 is a blue color filter. Also, in one embodiment, the first color filter CF1 is a blue color filter, the second color filter CF2 is a green color filter, and the third color filter CF3 is a red color filter. Also, in one embodiment, the first color filter CF1 is a red color filter, the second color filter CF2 is a blue color filter, and the third color filter CF3 is a green color filter. Also, in one embodiment, the first color filter CF1 is a green color filter, the second color filter CF2 is a blue color filter, and the third color filter CF3 is a red color filter.

As the first trench TRC1 overlapping the first color filter CF1, the second trench TRC2 overlapping the second color filter CF2, and the third trench TRC3 overlapping the third color filter CF3 have the different depths, distances from the bottom surface of the second electrode CAT to the bottom of the first reflective electrode RE1, to the bottom second reflective electrode RE2, to the bottom of the third reflective electrode RE3 disposed in each of the trenches are different. For example, the distance between the bottom of the first reflective electrode RE1 and the bottom surface of the second electrode CAT in the third direction DR3 is defined as the first resonance distance rd1, the distance between the bottom of the second reflective electrode RE2 and the bottom surface of the second electrode CAT in the third direction DR3 is defined as the second resonance distance rd2, and the distance between the bottom of the third reflective electrode RE3 and the bottom surface of the second electrode CAT in the third direction DR3 is defined as the third resonance distance rd3. In this case, the first resonance distance rd1, the second resonance distance rd2, and the third resonance distance rd3 are defined by the Relational Expression 1. Thus, the second resonance distance rd2 is longer than the third resonance distance rd3 and smaller than the first resonance distance rd1. Here, each of the first resonance distance rd1, the second resonance distance rd2, and the third resonance distance rd3 means the length in the third direction DR3.

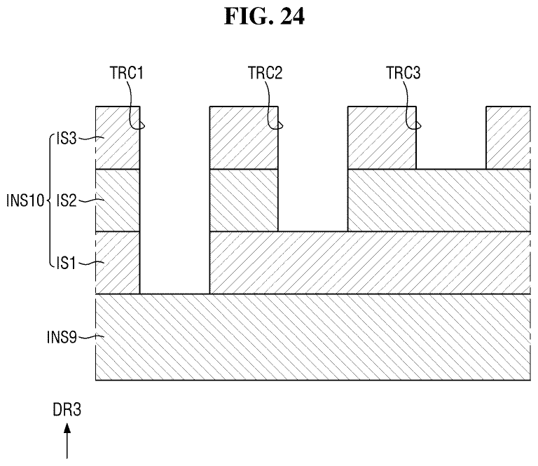

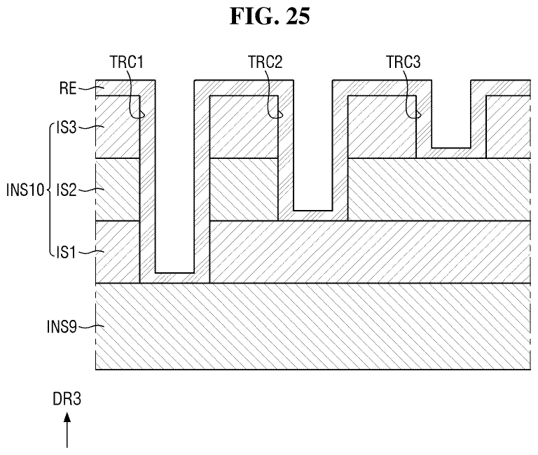

FIGS. 24 and 25 are cross-sectional views for illustrating a method for fabricating a display device according to one embodiment.

FIGS. 24 and 25 are cross-sectional views for the above-described display device of FIG. 23.

As illustrated in FIG. 24, the tenth interlayer insulating layer INS10 is disposed on the ninth interlayer insulating layer INS9. For example, the first insulating layer IS1 is disposed on the ninth interlayer insulating layer INS9, the second insulating layer IS2 is disposed on the first insulating layer IS1, and then the third insulating layer IS3 is disposed on the second insulating layer IS2. Next, the first trench TRC1, the second trench TRC2, and the third trench TRC3 are formed to penetrate at least some of the insulating layers of the tenth interlayer insulating layer INS10 in the third direction DR3. The first trench TRC1, the second trench TRC2, and the third trench TRC3 have different depths in the third direction DR3.

Thereafter, the reflective electrode RE is formed on the tenth interlayer insulating layer INS10. Here, the reflective electrode RE is further formed along the inner wall of the first trench TRC1, the inner wall of the second trench TRC2, and the inner wall of the third trench TRC3.

For a description of the subsequent processes, refer to, for example, FIGS. 17 to 22 described above and the relevant description.

It will be able to be understood by one of ordinary skill in the art to which the present disclosure belongs that the present disclosure may be implemented in other specific forms without changing the technical spirit or essential features of the present disclosure. Therefore, it is to be understood that the exemplary embodiments described above are illustrative rather than being restrictive in all aspects. It is to be understood that the scope of the present disclosure are defined by the claims rather than the detailed description described above and all modifications and alterations derived from the claims and their equivalents fall within the scope of the present disclosure.

What is claimed is:

1. A display device comprising:
a substrate;
an interlayer insulating layer disposed on the substrate and having a first trench and a second trench, wherein the first trench has a different depth from the second trench in a thickness direction;
a first reflective electrode disposed inside the first trench;
a second reflective electrode disposed inside the second trench;
a first-first electrode disposed on the interlayer insulating layer and connected to the first reflective electrode;
a first-second electrode disposed on the interlayer insulating layer and connected to the second reflective electrode;
a second electrode disposed on the first-first electrode and the first-second electrode;
a first color filter disposed on the second electrode to overlap the first-first electrode in the thickness direction; and
a second color filter disposed on the second electrode to overlap the first-second electrode in the thickness direction,
wherein the interlayer insulating layer includes a plurality of insulating layers,
at least two of the plurality of insulating layers contain different materials, and
at least one of the first trench or the second trench penetrates the plurality of insulating layers containing different materials of the interlayer insulating layer in the thickness direction.

2. The display device of claim 1, wherein a number of the insulating layers penetrated by the first trench in the thickness direction is different from a number of the insulating layers penetrated by the second trench in the thickness direction.

3. The display device of claim 1, wherein the interlayer insulating layer includes:
a first insulating layer; and
a second insulating layer disposed on the first insulating layer to be adjacent to the first insulating layer and containing a different material from the first insulating layer.

4. The display device of claim 3, wherein the interlayer insulating layer includes a plurality of first insulating layers and a plurality of second insulating layers disposed alternately.

5. The display device of claim 1, wherein the first reflective electrode is disposed along side and bottom walls of the first trench, and
the second reflective electrode is disposed along side and bottom walls of the second trench.

6. The display device of claim 5, wherein each of the first reflective electrode and the second reflective electrode has an U-shaped structure when viewed from a cross section.

7. The display device of claim 1, further comprising:
a first intermediate insulating layer disposed between the first reflective electrode and the first-first electrode of the first trench; and
a second intermediate insulating layer disposed between the second reflective electrode and the first-second electrode of the second trench.

8. The display device of claim 7, wherein one portion of the first intermediate insulating layer is surrounded by the first reflective electrode, and an other portion of the first intermediate insulating layer is surrounded by the first-first electrode, and
one portion of the second intermediate insulating layer is surrounded by the second reflective electrode, and an other portion of the second intermediate insulating layer is surrounded by the first-second electrode.

9. The display device of claim 7, wherein a depth of the first intermediate insulating layer in the thickness direction is different from a depth of the second intermediate insulating layer in the thickness direction.

10. The display device of claim 1, wherein a distance from a bottom surface of the second electrode to a bottom of the first reflective electrode, which is disposed at a bottommost portion of the first trench, is different from a distance from a bottom surface of the second electrode to a bottom of the second reflective electrode, which is disposed at a bottommost portion of the second trench.

11. The display device of claim 1, wherein the first-first electrode is connected to a transistor on the substrate through at least a contact hole connected to the first trench in the thickness direction.

12. The display device of claim 1, wherein the first-first electrode is connected to a transistor on the substrate through at least a contact hole penetrating the interlayer insulating layer in the thickness direction.

13. The display device of claim 12, further comprising an intermediate layer interposed between the first-first electrode and the first-second electrode and the second electrode.

14. The display device of claim 13, further comprising a pixel defining layer disposed between the first-first electrode and the first-second electrode to define emission areas having a first emission area and a second emission area,
wherein the first-first electrode overlaps the first emission area in the thickness direction, and the first-second electrode overlaps the second emission area in the thickness direction.

15. A method for fabricating a display device, comprising:
forming an interlayer insulating layer including a plurality of insulating layers on a substrate;
forming a first trench and a second trench having different depths in the interlayer insulating layer;
forming a reflective electrode disposed on side and bottom walls of the first trench and side and bottom walls of the second trench and disposed on the interlayer insulating layer;
forming an intermediate insulating layer disposed on the reflective electrode;
by removing the reflective electrode on the interlayer insulating layer and the intermediate insulating layer on the reflective electrode, forming a first reflective electrode and a second reflective electrode disposed along the side and bottom walls of the first trench and the side and bottom walls of the second trench, respectively, and separated from each other, and forming a first intermediate insulating layer and a second intermediate insulating layer disposed inside the first trench and the second trench, respectively, and separated from each other;
forming a first-first electrode disposed on the interlayer insulating layer and connected to the first reflective electrode and a first-second electrode disposed on the interlayer insulating layer and connected to the second reflective electrode; and
forming a second electrode disposed on the first-first electrode and the first-second electrode,
wherein at least two of the plurality of insulating layers contain different materials, and
at least one of the first trench or the second trench penetrates the plurality of insulating layers containing different materials of the interlayer insulating layer in a thickness direction.

16. The method of claim 15, wherein a number of the insulating layers penetrated by the first trench is different from a number of the insulating layers penetrated by the second trench.

17. The method of claim 15, wherein the interlayer insulating layer includes:
a first insulating layer; and
a second insulating layer disposed on the first insulating layer to be adjacent to the first insulating layer and containing a different material from the first insulating layer.

18. The method of claim 17, wherein the interlayer insulating layer includes a plurality of first insulating layers and a plurality of second insulating layers disposed alternately.

19. The method of claim 15, wherein each of the first reflective electrode and the second reflective electrode has an U-shaped structure when viewed from a cross section.

20. The method of claim 15, wherein a depth of the first intermediate insulating layer in the thickness direction is different from a depth of the second intermediate insulating layer in the thickness direction.

21. The method of claim 15, wherein a distance from a bottom surface of the second electrode to a bottom of the first reflective electrode, which is disposed at a bottommost portion of the first trench, is different from a distance from a bottom surface of the second electrode to a bottom of the second reflective electrode, which is disposed at a bottommost portion of the second trench.

22. The method of claim 15, wherein the removing of the reflective electrode and the intermediate insulating layer on the interlayer insulating layer is accomplished by chemical mechanical polishing.

23. The method of claim 15, further comprising:
after the forming the first-first electrode and the first-second electrode, forming a pixel defining layer disposed on edges of the first-first electrode and first-second electrode to define emission areas; and
forming an intermediate layer disposed between the pixel defining layer and the second electrode.
